(19) United States
(12) Patent Application Publication
(10) Pub. No.: US 2026/0113938 A1
(43) Pub. Date: Apr. 23, 2026

(54) THREE-DIMENSIONAL MEMORY DEVICE CONTAINING THERMALLY CONDUCTIVE AND INSULATING TRENCH FILL STRUCTURE AND METHODS FOR FORMING THE SAME USING LASER ANNEALING

(71) Applicant: Sandisk Technologies, Inc., Milpitas, CA (US)

(72) Inventors: Wataru MINAGAWA, Yokkaichi (JP); Tsutomu TANII, Yokkaichi (JP)

(21) Appl. No.: 18/920,034

(22) Filed: Oct. 18, 2024

(51) Int. Cl. H10B 43/27; H01L 23/00; H01L 25/00; H01L 25/065; H01L 25/18; H10B 80/00

(52) U.S. Cl. CPC H10B 43/27; H10B 80/00; H10W 90/00; H10W 80/211; H10W 80/312; H10W 80/327; H10W 90/792

(57) ABSTRACT

A memory device includes alternating stacks that are laterally spaced apart from each other by lateral isolation trench fill structures, and each of the alternating stacks includes a respective vertically alternating sequence of insulating layers and electrically conductive layers, memory openings vertically extending through a respective one of the alternating stacks, memory opening fill structures located in the memory openings, where each of the memory opening fill structures includes a respective vertical semiconductor channel and a respective vertical stack of memory elements, and a polycrystalline semiconductor source layer underlying the alternating stack and contacting bottom surfaces of the vertical semiconductor channels. Each of the lateral isolation trench fill structures includes a thermally conductive trench fill material portion that is vertically spaced from the polycrystalline semiconductor source layer by a thermally insulating material.

### FIELD

The present disclosure relates generally to the field of semiconductor devices, and particularly to a three-dimensional memory device containing thermally conductive and thermally insulating trench fill structure and methods for forming the same using laser annealing of a source layer with improved uniformity.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device includes alternating stacks that are laterally spaced apart from each other by lateral isolation trench fill structures, and each of the alternating stacks includes a respective vertically alternating sequence of insulating layers and electrically conductive layers, memory openings vertically extending through a respective one of the alternating stacks, memory opening fill structures located in the memory openings, where each of the memory opening fill structures includes a respective vertical semiconductor channel and a respective vertical stack of memory elements, and a polycrystalline semiconductor source layer underlying the alternating stack and contacting bottom surfaces of the vertical semiconductor channels. Each of the lateral isolation trench fill structures includes a thermally conductive trench fill material portion that is vertically spaced from the polycrystalline semiconductor source layer by a thermally insulating material.

According to another aspect of the present disclosure, a method of forming a memory device comprises: forming alternating stacks laterally spaced from each other by lateral isolation trenches over a carrier substrate, wherein each of the alternating stacks comprises a respective vertically alternating sequence of insulating layers and electrically conductive layers and embeds a respective set of memory opening fill structures, and wherein each of the memory opening fill structures comprises a respective vertical semiconductor channel and a respective stack of memory elements located at levels of the electrically conductive layers; forming lateral isolation trench fill structures in the lateral isolation trenches by anisotropically depositing a thermally insulating material in peripheral regions of the lateral isolation trenches and by subsequently depositing a thermally conductive trench fill material in center regions of the lateral isolation trenches, wherein each of the lateral isolation trench fill structures comprises a thermally insulating spacer and a thermally conductive trench fill material portion embedded within the thermally insulating spacer; removing the carrier substrate and exposing bottom end portions of the vertical semiconductor channels; depositing an amorphous semiconductor source layer on the exposed bottom end portions of the vertical semiconductor channels; and crystallizing the amorphous semiconductor source layer into a polycrystalline semiconductor source layer by laser annealing.

According to yet another aspect of the present disclosure, a method of forming a memory device comprises: forming alternating stacks laterally spaced from each other by lateral isolation trenches over a carrier substrate, wherein each of the alternating stacks comprises a respective vertically alternating sequence of insulating layers and electrically conductive layers and embeds a respective set of memory opening fill structures, and wherein each of the memory opening fill structures comprises a respective vertical semiconductor channel and a respective stack of memory elements located at levels of the electrically conductive layers; forming lateral isolation trench fill structures in the lateral isolation trenches by sequentially depositing a thermally and electrically insulating material and a thermally conductive trench fill material, wherein each of the lateral isolation trench fill structures comprises a thermally insulating spacer and a thermally conductive trench fill material portion embedded within the thermally insulating spacer; removing the carrier substrate; forming backside shallow trenches by removing bottom portions of the thermally insulating spacers; forming backside thermal isolation structures in the backside shallow trenches; exposing bottom end portions of the vertical semiconductor channels; depositing an amorphous semiconductor source layer on the exposed bottom end portions of the vertical semiconductor channels; and crystallizing the amorphous semiconductor source layer into a polycrystalline semiconductor source layer by laser annealing.

### BRIEF DESCRIPTION OF THE DRAWINGS

FIG. 1 is a schematic vertical cross-sectional view of a first exemplary structure after formation of an alternating stack of insulating layers and sacrificial material layers over a carrier substrate according to an embodiment of the present disclosure.

FIG. 2 is a schematic vertical cross-sectional view of the first exemplary structure after formation of stepped surfaces and a stepped dielectric material portion according to an embodiment of the present disclosure.

FIG. 3A is a schematic vertical cross-sectional view of the first exemplary structure after formation of memory openings and support openings according to an embodiment of the present disclosure.

FIG. 3B is a top-down view of the first exemplary structure of FIG. 3A. The hinged vertical cross-sectional plane A-A′ is the cut plane of the vertical cross-sectional view of FIG. 3A.

FIG. 4 is a schematic vertical cross-sectional view of the first exemplary structure after formation of sacrificial opening fill structures according to an embodiment of the present disclosure.

FIG. 5 is a vertical cross-sectional view of the first exemplary structure after formation of support pillar structures according to an embodiment of the present disclosure.

FIG. 6 is a schematic vertical cross-sectional view of the first exemplary structure after removal of sacrificial memory opening fill structures according to an embodiment of the present disclosure.

FIGS. 7A-7F are sequential vertical cross-sectional views of a memory opening during formation of a memory opening fill structure according to an embodiments of the present disclosure.

FIG. 8A is a schematic vertical cross-sectional view of the first exemplary structure after formation of memory opening fill structures according to an embodiment of the present disclosure.

FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of lateral isolation trenches according to an embodiment of the present disclosure.

FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of dielectric isolation liners according to an embodiment of the present disclosure.

FIG. 11 is a vertical cross-sectional view of the first exemplary structure after formation of lateral recesses according to an embodiment of the present disclosure.

FIG. 12 is a vertical cross-sectional view of the first exemplary structure after formation of electrically conductive layers according to an embodiment of the present disclosure.

FIG. 13 is a vertical cross-sectional view of the first exemplary structure after anisotropic deposition of an insulating material layer according to an embodiment of the present disclosure.

FIG. 14 is a vertical cross-sectional view of the first exemplary structure after anisotropic deposition of a thermally conductive fill material layer according to an embodiment of the present disclosure.

FIG. 15 is a vertical cross-sectional view of the first exemplary structure after formation of lateral isolation trench fill structures according to an embodiment of the present disclosure.

FIG. 16A is a vertical cross-sectional view of the first exemplary structure after formation of layer contact via structures and drain contact via structures according to an embodiment of the present disclosure.

FIG. 16B is a top-down view of the first exemplary structure of FIG. 16A. FIG. 16B is a top-down view of the first exemplary structure of FIG. 16A. The vertical plane A-A is the cut plane of the vertical cross-sectional view of FIG. 16A.

FIG. 17 is a vertical cross-sectional view of the first exemplary structure after formation of a memory die according to an embodiment of the present disclosure.

FIG. 18 is a vertical cross-sectional view of a logic die according to an embodiment of the present disclosure.

FIG. 19 is a vertical cross-sectional view of the first exemplary structure after attaching the logic die to the memory die according to an embodiment of the present disclosure.

FIG. 20 is a vertical cross-sectional view of the first exemplary structure after removal of the carrier substrate according to an embodiment of the present disclosure.

FIG. 21 is a vertical cross-sectional view of the first exemplary structure after removal of end portions of the memory films according to an embodiment of the present disclosure.

FIG. 22 is a vertical cross-sectional view of the first exemplary structure after deposition of an amorphous semiconductor source layer according to an embodiment of the present disclosure.

FIG. 23 is a vertical cross-sectional view of the first exemplary structure after conversion of the amorphous semiconductor source layer into a polycrystalline semiconductor source layer according to an embodiment of the present disclosure.

FIG. 24 is a vertical cross-sectional view of the first exemplary structure after patterning the polycrystalline semiconductor source layer according to an embodiment of the present disclosure.

FIG. 25 is a vertical cross-sectional view of the first exemplary structure after formation of a backside dielectric layer and source contact structures according to an embodiment of the present disclosure.

FIG. 26 is a vertical cross-sectional view of a second exemplary structure after anisotropic deposition of an insulating material layer according to an embodiment of the present disclosure.

FIG. 27 is a vertical cross-sectional view of the second exemplary structure after anisotropic deposition of a thermally conductive fill material layer according to an embodiment of the present disclosure.

FIG. 28 is a vertical cross-sectional view of the second exemplary structure after formation of lateral isolation trench fill structures according to an embodiment of the present disclosure.

FIG. 29 is a vertical cross-sectional view of the second exemplary structure after formation of a memory die and after attaching the logic die to the memory die and removing the carrier substrate according to an embodiment of the present disclosure.

FIG. 30 is a vertical cross-sectional view of the second exemplary structure after removal of the carrier substrate according to an embodiment of the present disclosure.

FIG. 31 is a vertical cross-sectional view of the second exemplary structure after formation of backside shallow trenches according to an embodiment of the present disclosure.

FIG. 32 is a vertical cross-sectional view of the second exemplary structure after formation of a backside dielectric fill material layer according to an embodiment of the present disclosure.

FIG. 33 is a vertical cross-sectional view of the second exemplary structure after formation of shallow trench isolation structures according to an embodiment of the present disclosure.

FIG. 34 is a vertical cross-sectional view of the second exemplary structure after removal of end portions of the memory films according to an embodiment of the present disclosure.

FIG. 35 is a vertical cross-sectional view of the second exemplary structure after deposition of an amorphous semiconductor source layer according to an embodiment of the present disclosure.

FIG. 36 is a vertical cross-sectional view of the second exemplary structure after conversion of the amorphous semiconductor source layer into a polycrystalline semiconductor source layer according to an embodiment of the present disclosure.

FIG. 37 is a vertical cross-sectional view of the second exemplary structure after patterning the polycrystalline semiconductor source layer according to an embodiment of the present disclosure.

FIG. 38 is a vertical cross-sectional view of the second exemplary structure after formation of a backside dielectric layer and source contact structures according to an embodiment of the present disclosure.

### DETAILED DESCRIPTION

Thermally and electrically conductive materials, such as tungsten, can be deposited in lateral isolation trenches in three-dimensional memory devices to counteract the effect of stress imposed by tungsten word lines on the substrate, which may cause the substrate to warp. However, the present inventors realized that thermally conductive tungsten located in the lateral isolation trenches can act as a heat diffusion path during laser crystallization anneal of a semiconductor source layer, which may result in an insufficient crystallization of portions of the semiconductor source layer located adjacent to such heat diffusion (e.g., heat dissipation) paths. This may lead to open circuits between the semiconductor channels of the three-dimensional memory device and the high resistivity, insufficiently crystallized portions of the semiconductor source layer.

Specifically, when an amorphous semiconductor source layer (e.g., a doped amorphous silicon layer) is subjected to laser annealing to form a polycrystalline semiconductor source layer (e.g., a doped polysilicon layer), heat absorption into adjacent thermally conductive materials, such as tungsten located in lateral isolation trench fill structures, can result in non-uniform temperature distribution in the source layer. The conductive material dissipates heat from the laser radiation, leading to insufficient crystallization in adjacent regions of the polycrystalline semiconductor source layer.

Embodiments of the present disclosure are directed to a three-dimensional memory device containing thermally conductive and thermally insulating trench fill structure. The thermally and electrically conductive portion of the trench fill structure improves die strength and reduces die warpage by counteracting the stress imposed by the word lines on the substrate, while the thermally and electrically insulating portion of the trench fill structure reduces heat dissipation through the thermally conductive portion during a laser crystallization anneal of the semiconductor source layer. This results in an improved laser anneal uniformity, and leads to an improved crystallization of the semiconductor source layer, and thus a reduction in open circuits between semiconductor channels and the crystallized source layer.

Specifically, the thermally insulating material acts as both a thermal barrier and as a spacer which provides a greater vertical separation between the conductive material within each lateral isolation trench fill structure and the amorphous semiconductor source layer. This reduces heat dissipation through the thermally conductive material in the lateral isolation trench and minimizes temperature gradients in the semiconductor source layer. As a result, the annealing process produces a more uniform polycrystalline structure in the semiconductor source layer.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵/m to 1×10⁵ S/m. As used herein, a “semiconductor material” refers to a material having electrical conductivity in the range from 1×10⁻⁵/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

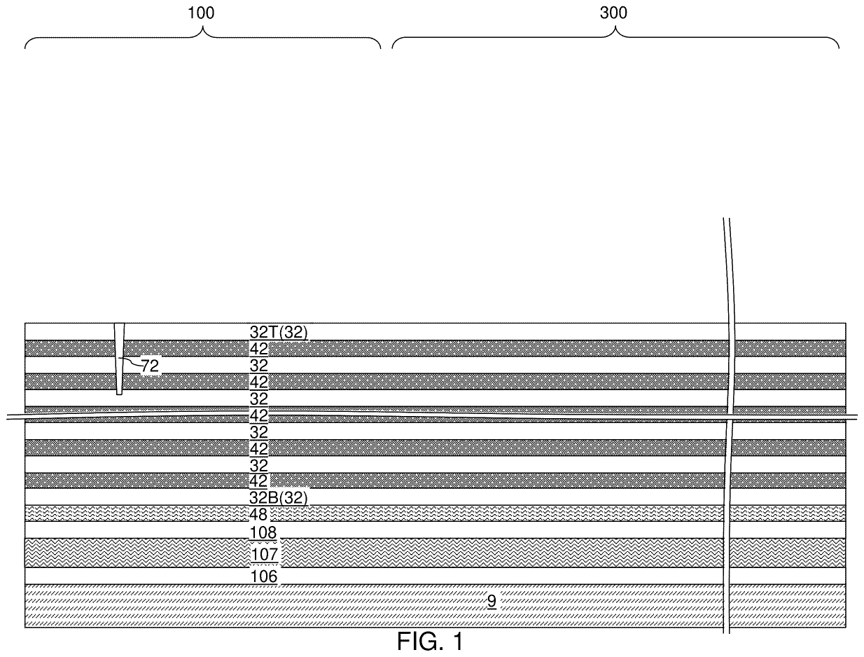

Referring to FIG. 1, a first exemplary structure according to an embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selectively the materials of insulating layers 32 and dielectric material portions to be subsequently formed.

An optional sacrificial stopper layer 106, an optional sacrificial etch-stop layer 107, an optional source isolation dielectric layer 108, and/or an optional source-side electrode layer 48 may be sequentially formed over the carrier substrate 9. The optional sacrificial stopper layer 106 may comprise a material that may be employed as a stopper material during subsequent removal of the carrier substrate 9. For example, if the carrier substrate 9 comprises a semiconductor material, such as silicon, the sacrificial stopper layer 106 may comprise a dielectric material, such as silicon oxide or silicon nitride, and may have a thickness in a range from 50 nm to 1,000 nm, although lesser and greater thicknesses may also be employed. The optional sacrificial etch-stop layer 107 may comprise a sacrificial material that may be subsequently removed selective to materials of the source isolation dielectric layer 108 and memory films to be subsequently employed. For example, the sacrificial etch-stop layer 107 may comprise a semiconductor material such as silicon, and may have a thickness in a range from 50 nm to 1,000 nm, although lesser and greater thicknesses may also be employed. The source isolation dielectric layer 108 comprises a dielectric material such as silicon oxide, and may have a thickness in a range from 50 nm to 1,000 nm, although lesser and greater thicknesses may also be employed. The source-side electrode layer 48 comprises a conductive material such as a heavily-doped semiconductor material. The thickness of the source-side electrode layer 48 may be in a range from 30 nm to 300 nm, although lesser and greater thicknesses may also be employed.

An alternating stack of first material layers and second material layers can be formed over the carrier substrate 9 and over the optional sacrificial stopper layer 106, the optional sacrificial etch-stop layer 107, the optional source isolation dielectric layer 108, and/or the optional source-side electrode layer 48. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or silicon-germanium. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 may be a continuous insulating layer that laterally extends over the entire area of the carrier substrate 9. Each of the sacrificial material layers 42 may be a continuous sacrificial material layer that laterally extends over the entire area of the carrier substrate 9. Thus, the alternating stack (32, 42) may comprise a vertically alternating sequence of the continuous insulating layers and the continuous sacrificial material layers.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed. Drain-select-level isolation structures 72 laterally extending along a first horizontal direction hd1 may be formed through a subset of the uppermost sacrificial material layers 42 that will be replaced with drain side select gate electrodes.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

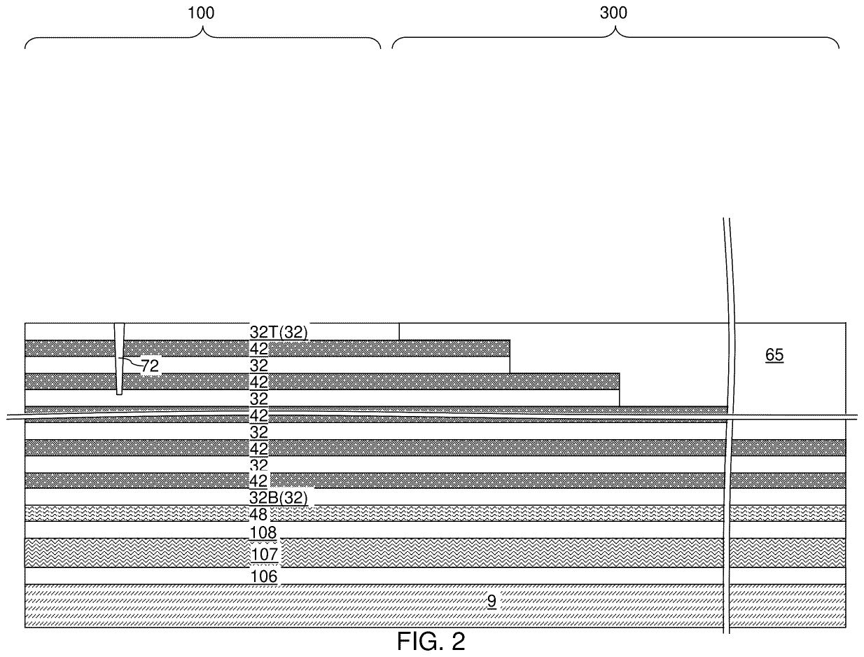

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

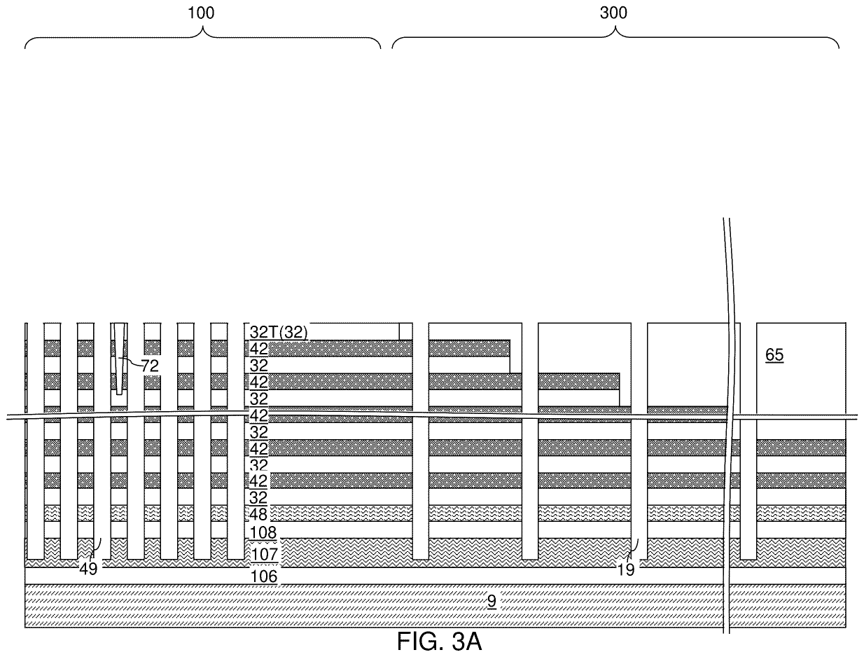

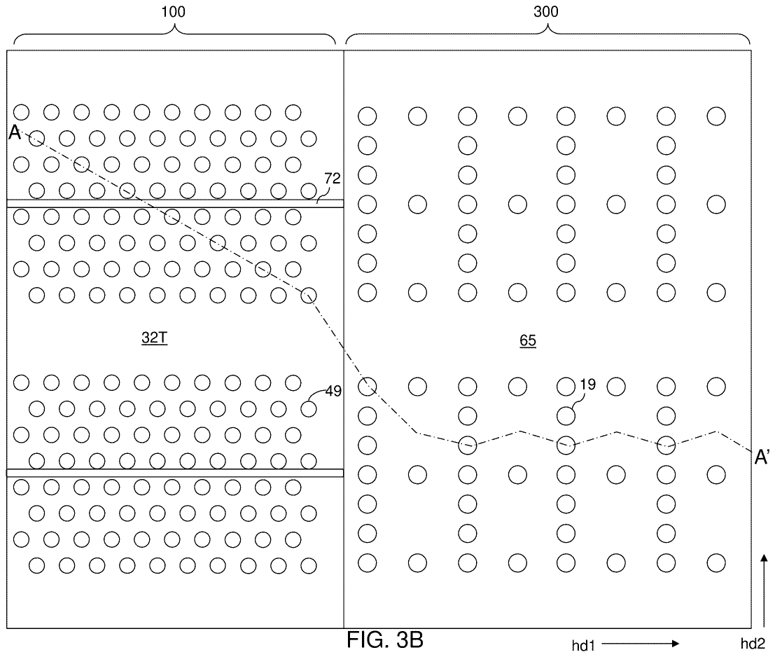

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 may be optionally formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater diameters may be employed. The support openings 19 may have a diameter in a range from 60 nm to 400 nm, such as from 120 nm to 300 nm, although lesser and greater diameters may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction (e.g., word line direction) hd1 with a uniform pitch. The rows of memory openings 49 may be laterally spaced from each other along the second horizontal direction (e.g., bit line direction) hd2, which may be perpendicular to the first horizontal direction hd1. In one embodiment, each cluster of memory openings 49 may be formed as a two-dimensional periodic array of memory openings 49.

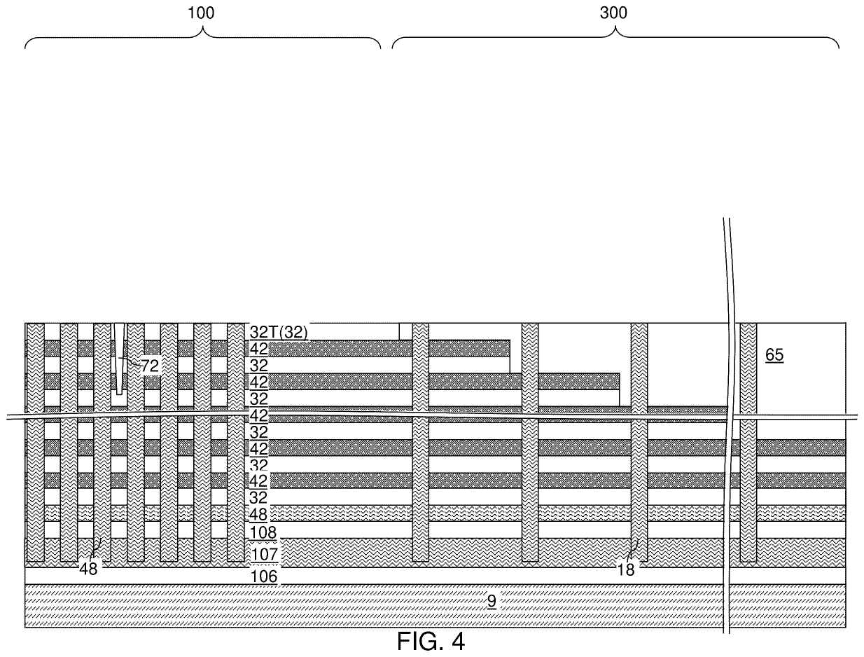

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium alloy), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

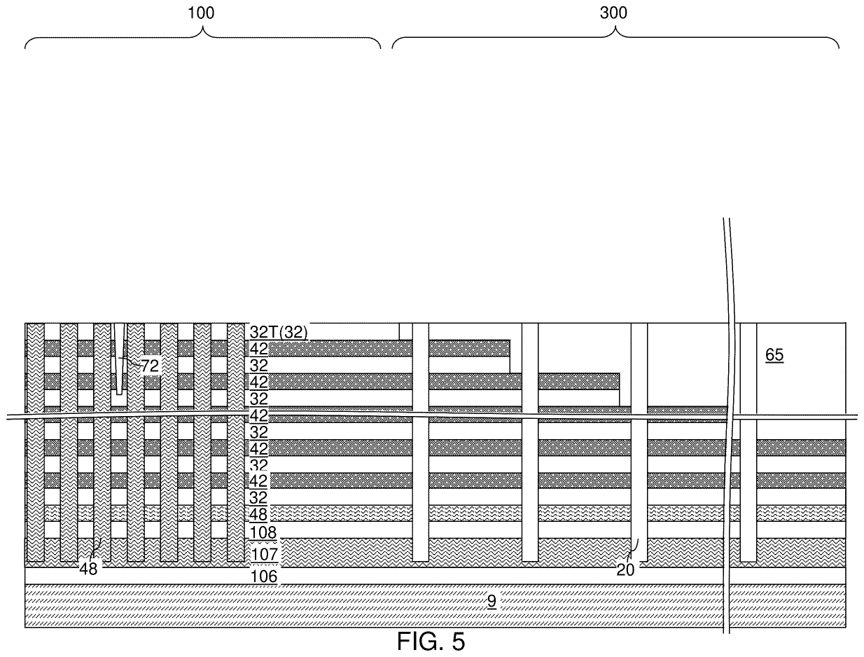

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

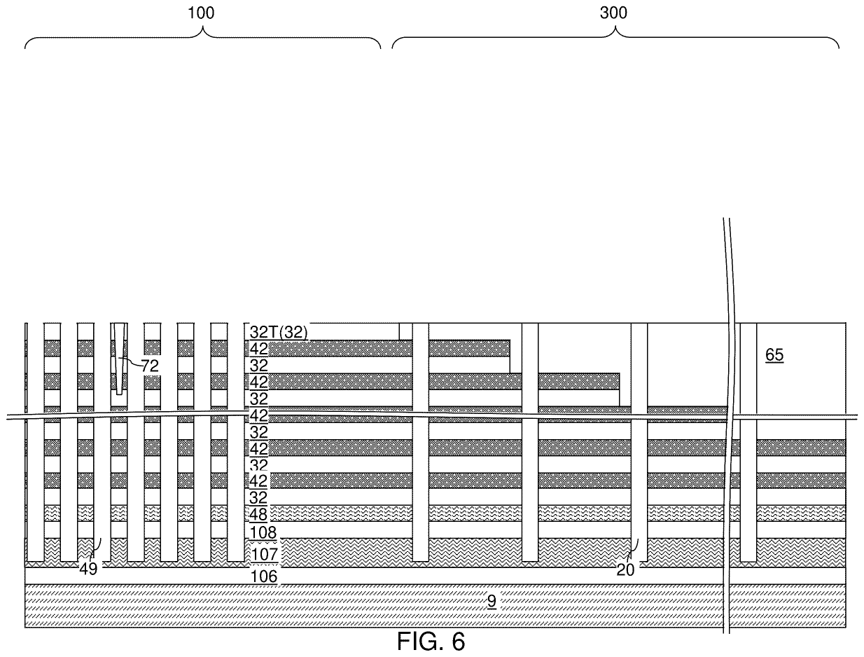

Referring to FIG. 6, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

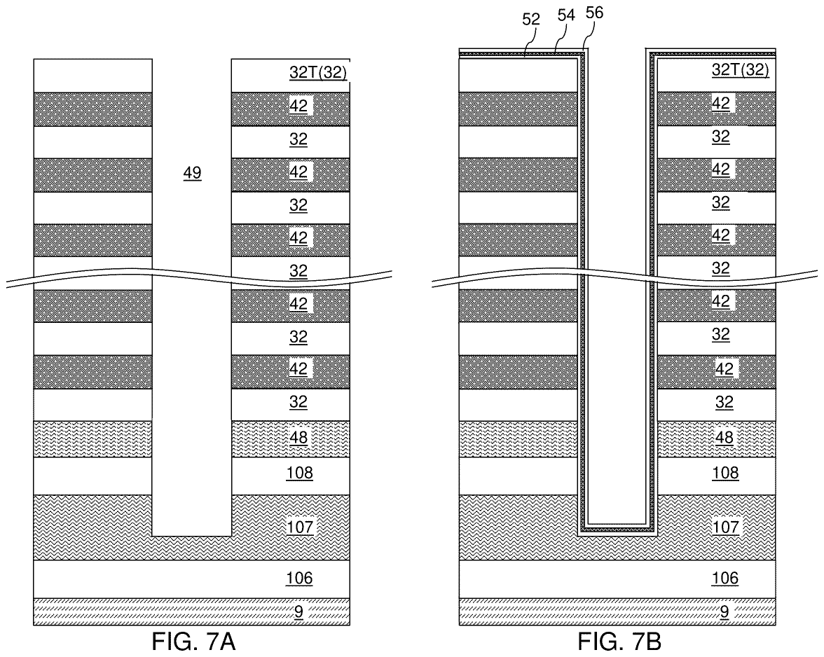

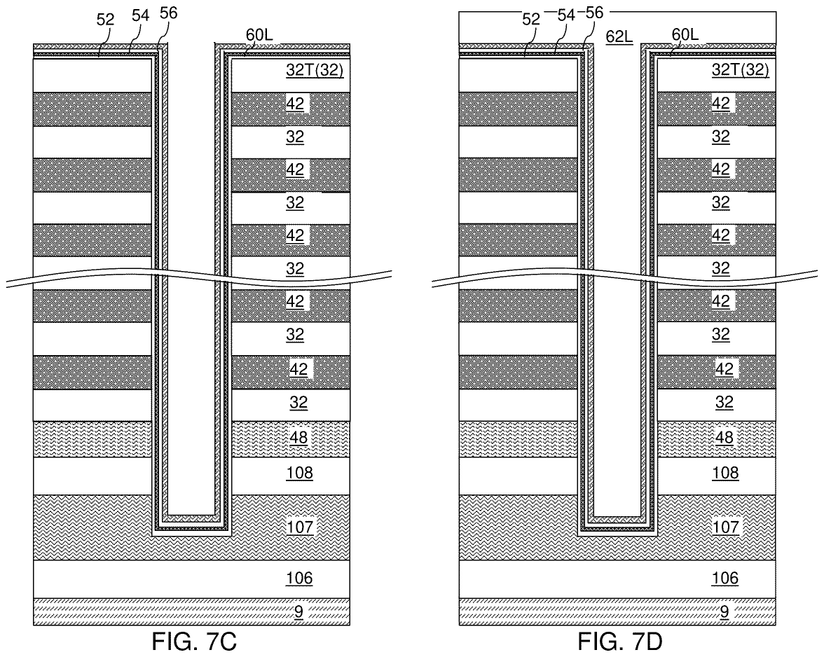

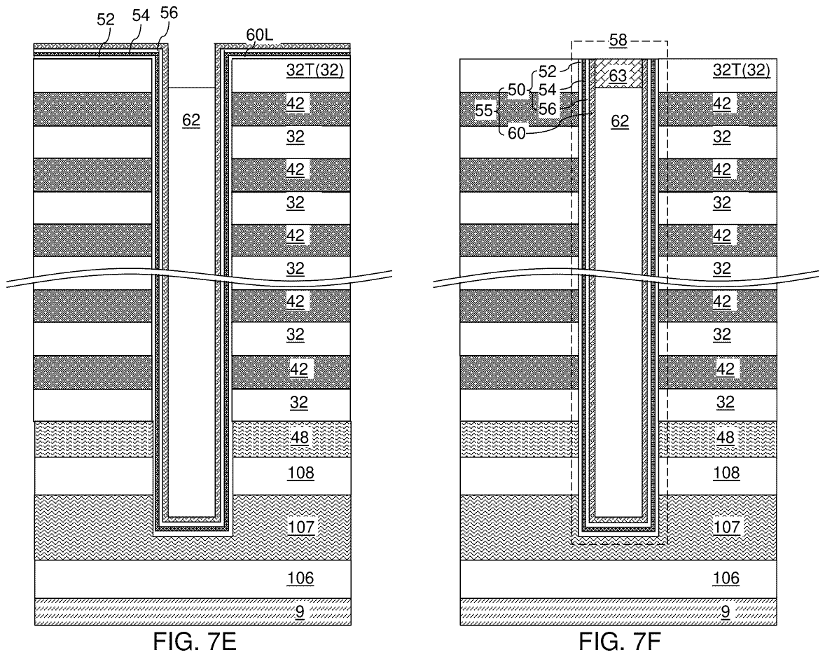

FIGS. 7A-7F are sequential vertical cross-sectional views of a memory opening 49 during formation of a memory opening fill structure 58 according to an embodiments of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layer 32T. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along long a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

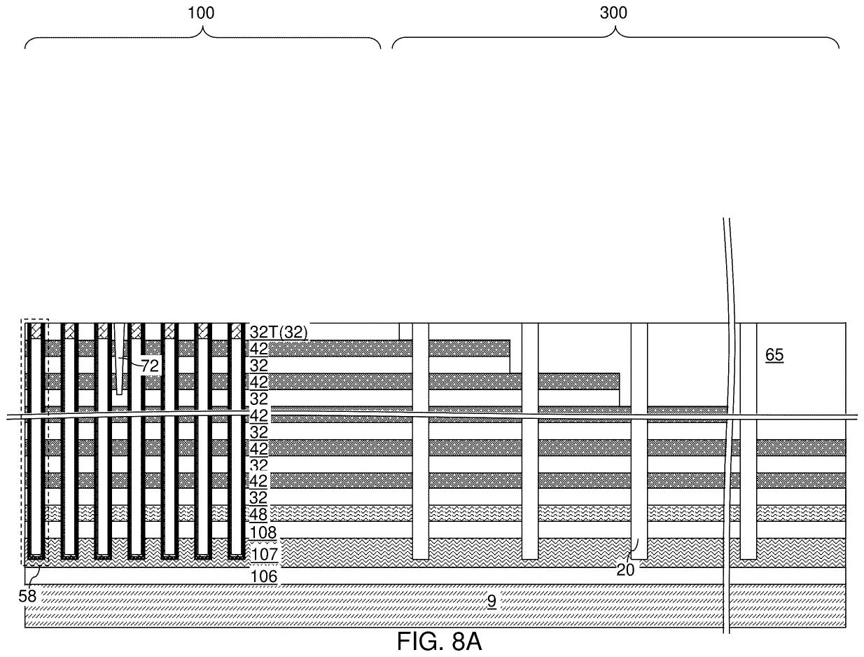

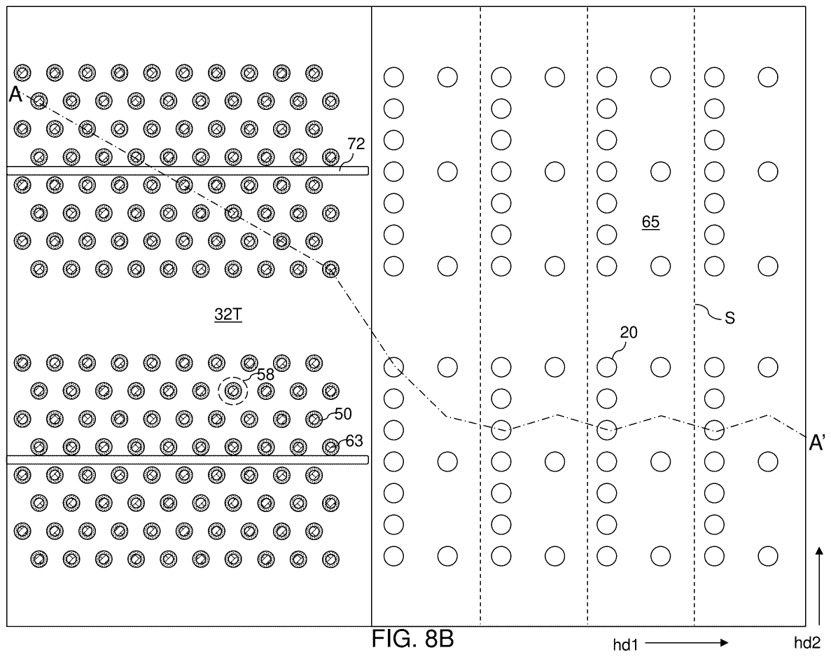

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

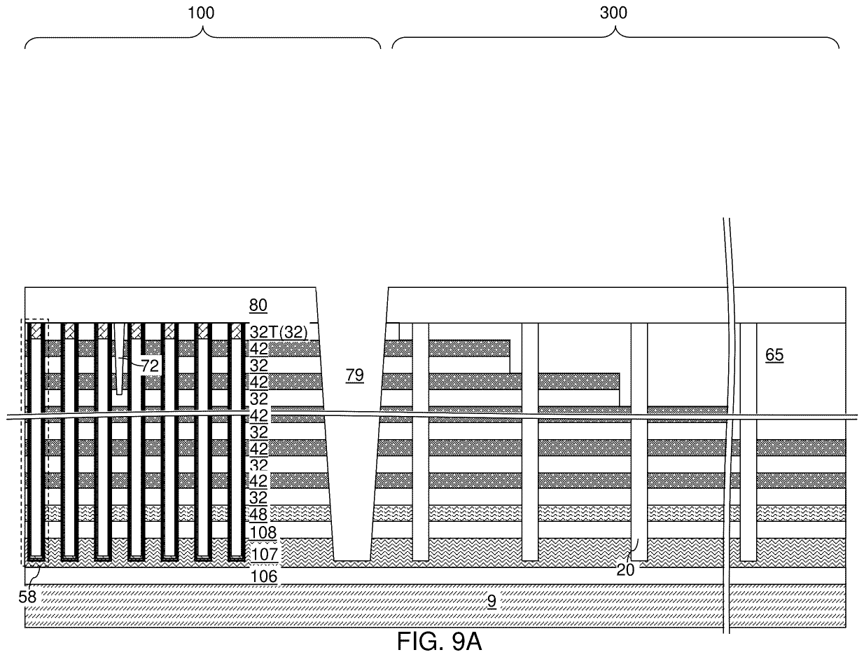

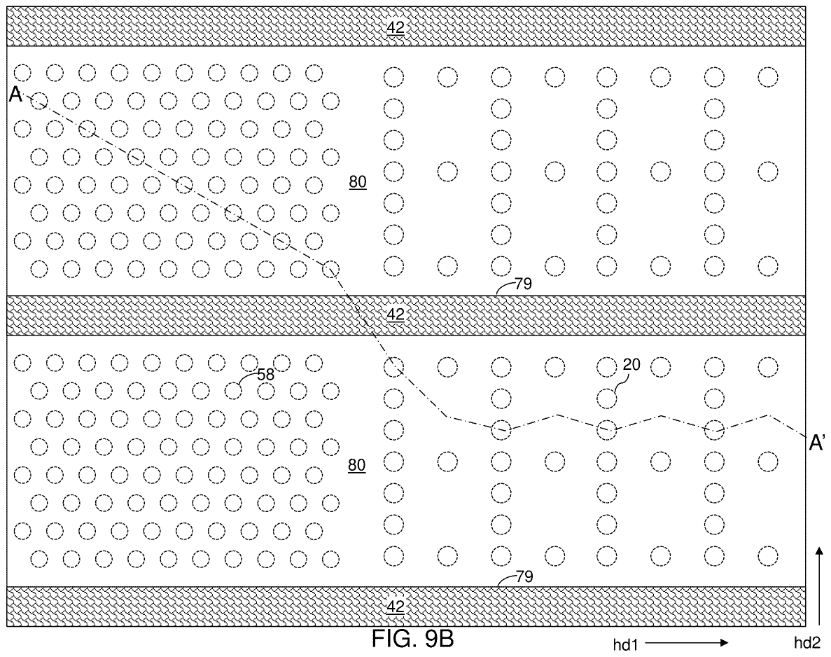

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and into underlying material layers. For example, the pattern of the openings in the photoresist layer may be transferred through the optional source-side electrode layer 48, the optional source isolation dielectric layer 108, and into an upper portion of the optional sacrificial etch-stop layer 107, if present. In one embodiment, the anisotropic etch process may comprise a first anisotropic etch step that etches the materials of the contact-level dielectric layer 80, the alternating stack (32, 42), and the stepped dielectric material portion 65 selectively to the material of the source-side electrode layer 48; a second anisotropic etch step that etches the material of the source-side electrode layer 48 selectively to the material of the source isolation dielectric layer 108; a third anisotropic etch step that etches the material of the source isolation dielectric layer 108 selectively to the material of the sacrificial etch-stop layer 107; and a fourth anisotropic etch step that etches the material of the sacrificial etch-stop layer 107 at a controlled etch rate. The vertical etch distance of the fourth anisotropic etch step into the sacrificial etch-stop layer 107 may be in a range from 50 nm to 200 nm, although lesser and greater vertical etch distances may also be employed.

Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 into the sacrificial etch-stop layer 107. Each of the lateral isolation trenches 79 may comprise a respective pair of end sidewalls that are perpendicular to the first horizontal direction and vertically extend from the top surface of the contact-level dielectric layer 80 to into the sacrificial etch-stop layer 107. Each sidewall of the lateral isolation trenches 79 may be free of any lateral step. In one embodiment, all sidewalls of the lateral isolation trenches 79 may be tapered such that the width of each lateral isolation trench 79 along the second horizontal direction hd2 may increase strictly with a vertical distance from the carrier substrate 9.

The contact-level dielectric layer 80 can be divided into multiple contact-level dielectric layers 80 that are laterally spaced apart from each other by the lateral isolation trenches 79. The source-side electrode layer 48 can be divided into multiple source-side electrode layers 48 that are laterally spaced apart from each other by the lateral isolation trenches 79. The source isolation dielectric layer 108 can be divided into multiple source isolation dielectric layers 108 that are laterally spaced apart from each other by the lateral isolation trenches 79. The photoresist layer can be subsequently removed, for example, by ashing.

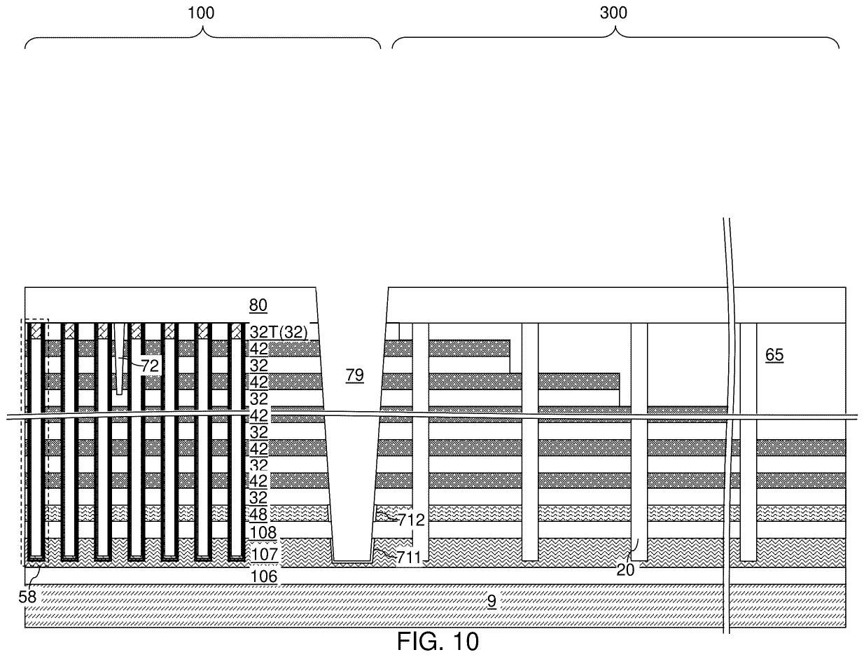

Referring to FIG. 10, an oxidation process may be performed to convert all physically exposed surface portions of semiconductor materials into dielectric isolation liners (711, 712), which may be semiconductor oxide liners (e.g., silicon oxide liners). For example, if the sacrificial etch-stop layer 107 comprises a semiconductor material such as polysilicon, first dielectric isolation liners 711 may be formed through oxidation of physically exposed surface portions of the sacrificial etch-stop layer 107. If the source-side electrode layers 48 comprise a heavily-doped semiconductor material such as heavily-doped polysilicon, second dielectric isolation liners 712 may be formed through oxidation of physically exposed surface portions of the source-side electrode layers 48. The thicknesses of the dielectric isolation liners (711, 712) may be in a range from 4 nm to 20 nm, although lesser and greater thicknesses may also be employed.

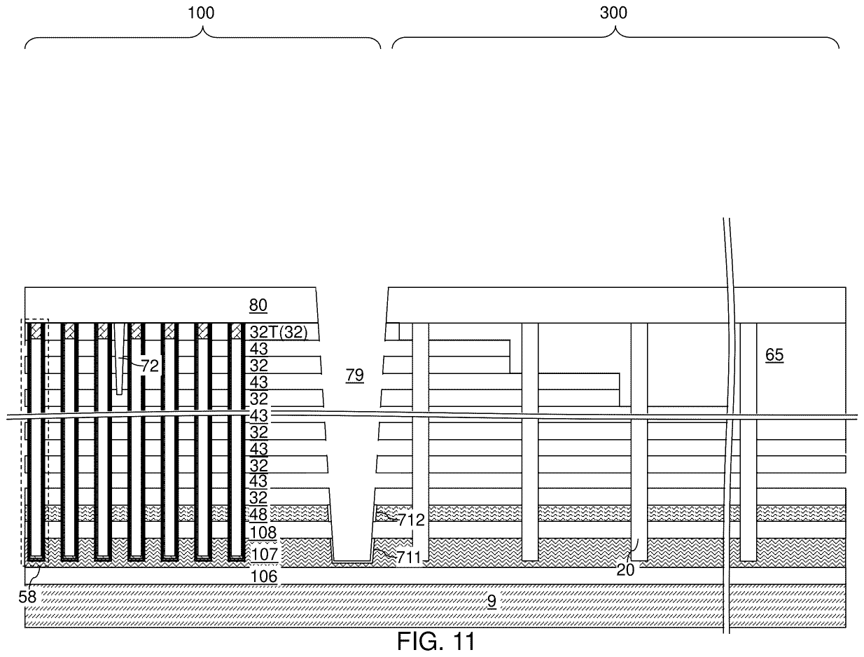

Referring to FIG. 11, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

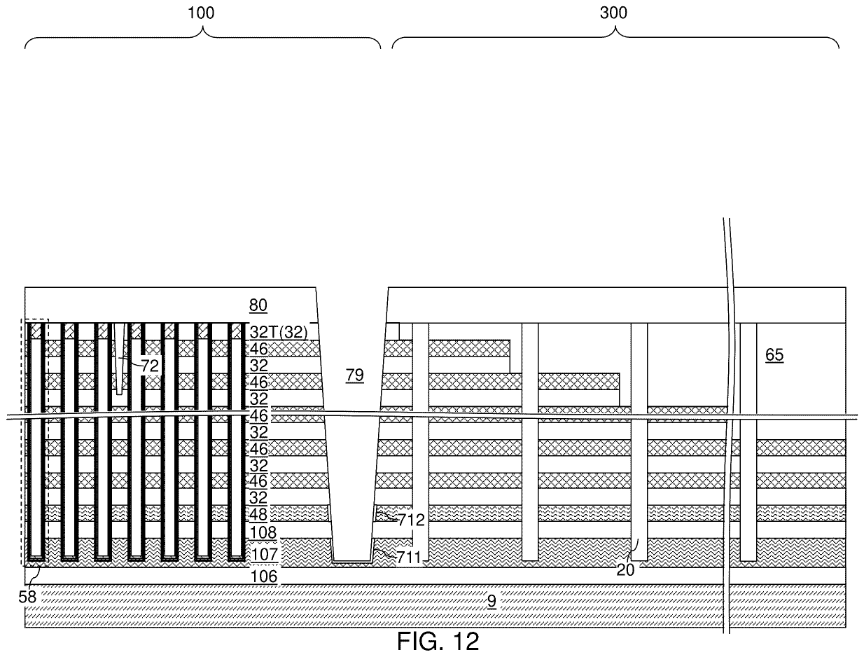

Referring to FIG. 12, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings that comprise the memory opening fill structures 58.

In summary, alternating stacks (32, 46) laterally spaced apart from each other by lateral isolation trenches 79 can be formed over a carrier substrate 9. Each of the alternating stacks (32, 46) comprises a respective vertically alternating sequence of insulating layers 32 and electrically conductive layers 46 and embeds a respective set of memory opening fill structures 58. Memory openings 49 vertically extend through a respective one of the alternating stacks (32, 46). Memory opening fill structures 58 can be located in the memory openings 49. Each of the memory opening fill structures 58 comprises a respective vertical semiconductor channel 60 and a respective stack of memory elements (which may comprise portions of a memory film 50) located at levels of the electrically conductive layers 46.

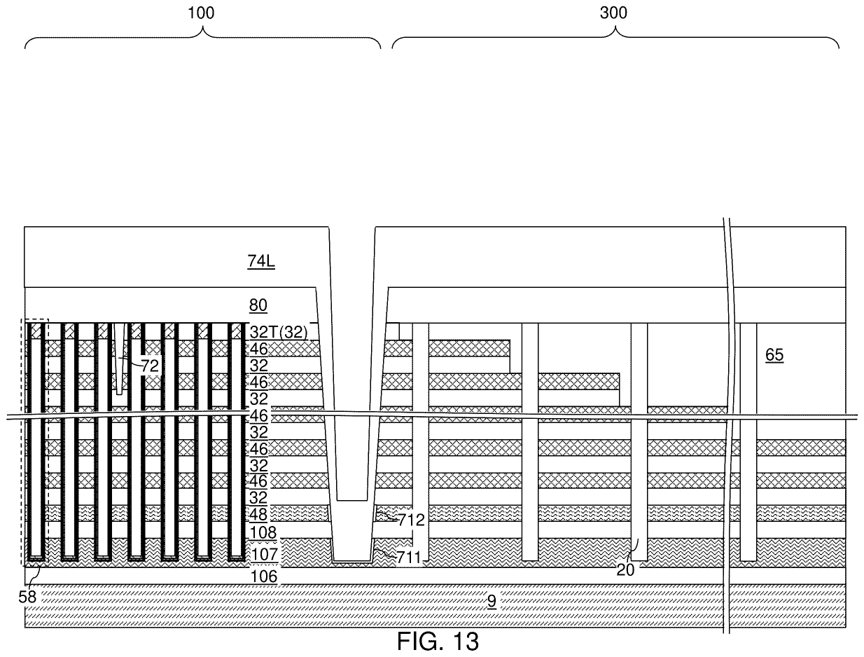

Referring to FIG. 13, a thermally insulating material can be anisotropically deposited in peripheral regions of the lateral isolation trenches 79 and over the contact-level dielectric layers 80 to form a thermally insulating material layer 74L. The thermally insulating material may comprise any material that has a thermal conductivity of less than 20 W/m*K, such as 0.1 to 15 W/m*K, including 1 to 10 W/m*K. Examples of thermally insulating materials include silicon oxide (e.g., undoped silicon oxide) having a thermal conductivity of about 1.38 W/m*K, amorphous silicon having a thermal conductivity of about 3.3 W/m*K, and polysilicon, having a thermal conductivity of about 10 W/m*K.

If the thermally insulating material is electrically conductive (e.g., polysilicon), then an electrically insulating liner, such as a silicon oxide liner, may be deposited into the peripheral regions of the lateral isolation trenches 79, prior to deposition of the thermally insulating material layer 74L on the electrically insulating liner. If the thermally insulating material is electrically insulating (e.g., silicon oxide), then the electrically insulating liner may be omitted.

The thermally insulating material may be anisotropically deposited using a directional deposition process, such as a plasma-enhanced chemical vapor deposition process. The anisotropic nature of the deposition process causes the lateral thickness of the thermally insulating material layer 74L on sidewalls of the lateral isolation trenches 79 to be less than the vertical thickness of the horizontally-extending portions of the thermally insulating material layer 74L over the contact-level dielectric layers 80 and to be less than the vertical thickness of bottom portions of the thermally insulating material layer 74L located at the bottom of the lateral isolation trenches 79. In one embodiment, the vertically-extending portions of the thermally insulating material layer 74L on the sidewalls of the lateral isolation trenches 79 may have a variable lateral thickness that decreases as a function of a vertical distance from the carrier substrate 9. In one embodiment, the vertical thickness of the bottom portions of the thermally insulating material layer 74L located at the bottom of the lateral isolation trenches 79 may be selected such that the bottommost recessed segments of the contoured top surface of the thermally insulating material layer 74L is formed above the horizontal plane including the bottommost surfaces of the alternating stacks (32, 46). In one embodiment, the bottommost recessed segments of the contoured top surface of the thermally insulating material layer 74L is formed above the source-side electrode layers 48. In an illustrative example, the vertical thickness of the bottom portions of the thermally insulating material layer 74L located at the bottom of the lateral isolation trenches 79 may be in a range from 200 nm to 2,000 nm, such as from 400 nm to 1,000 nm, although lesser and greater thicknesses may also be employed.

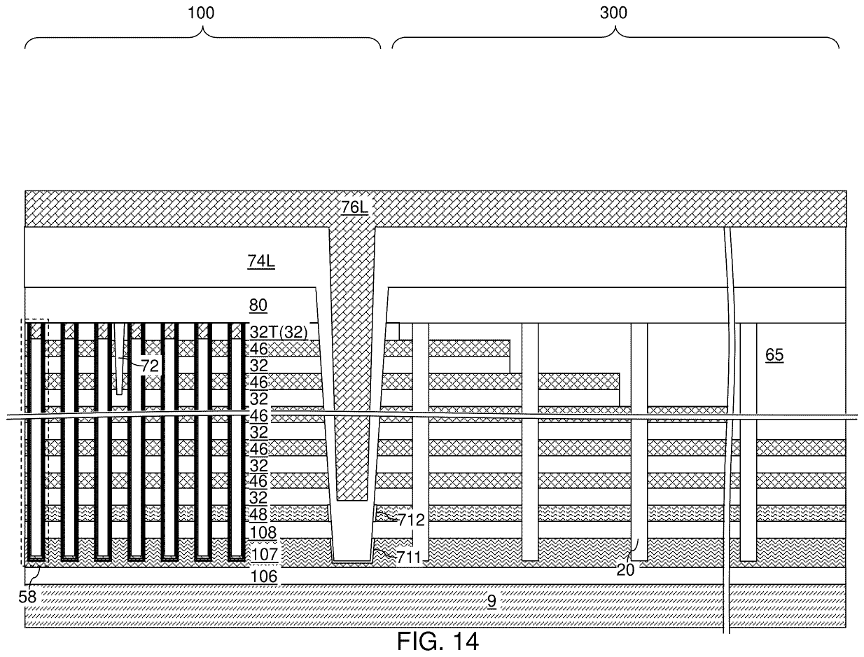

Referring to FIG. 14, at least one thermally conductive fill material such as at least one metallic material may be conformally deposited in remaining volumes of the lateral isolation trenches 79 and over the horizontally-extending portions of the thermally insulating material layer 74L to form a thermally conductive fill material layer 76L. In one embodiment, the at least one thermally conductive fill material may comprise least one electrically conductive material. The material composition of the thermally conductive fill material layer 76L may be selected such that the overall mechanical stress in the alternating stacks (32, 46) is minimized upon subsequent removal of material portions overlying the top surfaces of the contact-level dielectric layers 80. For example, the thermally conductive fill material layer 76L may comprise a refractory metal nitride (such as TiN, TaN, WN, and/or MoN) and/or a refractory metal (W, Mo, Ti, Ta, etc.), which counteracts the stress imposed by the electrically conductive layers (e.g., refractory metal or metal nitride layers) 46 on the carrier substrate 9.

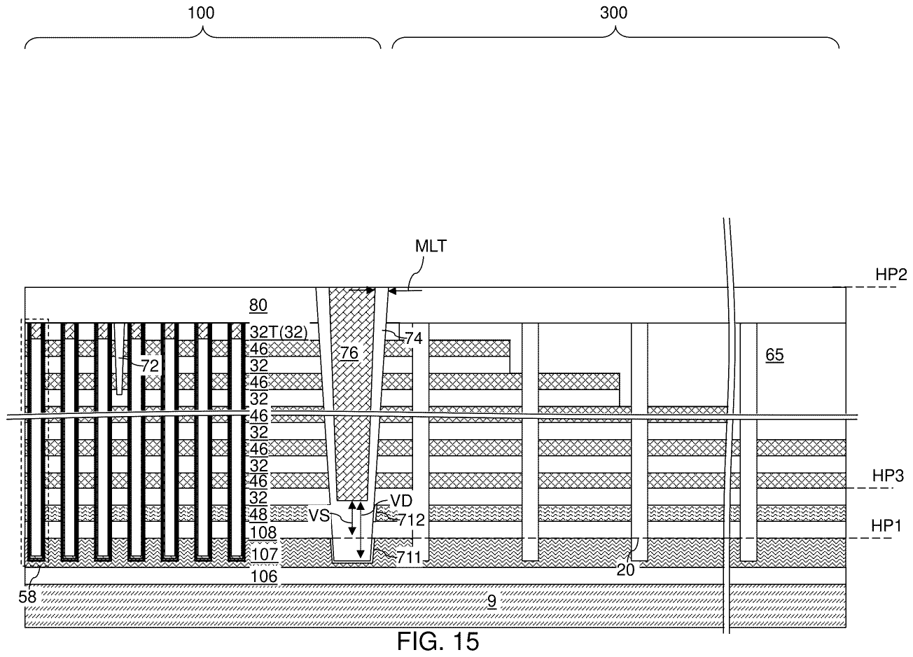

Referring to FIG. 15, a planarization process can be performed to remove portions of the thermally conductive fill material layer 76L and the thermally insulating material layer 74L that overlie a horizontal plane including top surfaces of the contact-level dielectric layers 80. The planarization process may comprise at least one recess etch process and/or at least one chemical mechanical polishing process. In one embodiment, at least a terminal step of the planarization process may comprise a chemical mechanical polishing process. Each remaining portion of the thermally conductive fill material layer 76L comprises a thermally conductive trench fill material portion 76. Each remaining portion of the thermally insulating material layer 74L comprises a thermally insulating spacer 74. Each contiguous combination of a thermally insulating spacer 74 and a thermally conductive trench fill material portion 76 constitutes a lateral isolation trench fill structure (74, 76).

In summary, the lateral isolation trench fill structures (74, 76) can be formed in the lateral isolation trenches 79 by anisotropically depositing a thermally insulating material in peripheral regions of the lateral isolation trenches 79, by subsequently depositing a thermally conductive trench fill material in center regions of the lateral isolation trenches 79, and by removing portions of the thermally conductive trench fill material and the thermally insulating material from outside the volumes of the lateral isolation trenches 79. Each of the lateral isolation trench fill structures (74, 76) comprises a thermally insulating spacer 74 and a thermally conductive trench fill material portion 76 embedded within the thermally insulating spacer 74. Each thermally conductive trench fill material portion 76 may have a respective bottommost surface that is vertically spaced from a bottom surface of the thermally insulating spacer 74 by a vertical distance VD that is greater than a maximum lateral thickness MLT of the thermally insulating spacer 74 at the top of the surfaces of the lateral isolation trench fill structures (74, 76).

In one embodiment, the top surface of the sacrificial etch-stop layer 107 may be formed within a first horizontal plane HP1. In one embodiment, the top surfaces of the lateral isolation trench fill structures (74, 76) may be formed within a second horizontal plane HP2. In one embodiment, the bottommost surfaces of the electrically conductive layers 46 may be formed within a third horizontal plane HP3 located between the first horizontal plane HP1 and the second horizontal plane HP2.

In one embodiment, within each of the lateral isolation trench fill structures (74, 76), all sidewall surfaces of the thermally conductive trench fill material portion 76 may be in direct contact with the thermally insulating spacer 74. In one embodiment, within each of the lateral isolation trench fill structures (74, 76), the thermally insulating spacer 74 may comprise a bottom portion located below the thermally conductive trench fill material portion 76 and contacting a surface (such as a bottom surface) of the thermally conductive trench fill material portion 76 that is proximal to the first horizontal plane HP1.

In one embodiment, the contact-level dielectric layers 80 may overlie a respective one of the alternating stacks (32, 46), and may be laterally spaced apart from each other by the lateral isolation trench fill structures (74, 76). In one embodiment, top surfaces of the lateral isolation trench fill structures (74, 76) are located entirely within the second horizontal plane HP2 which includes top surfaces of the contact-level dielectric layers 80.

In one embodiment, bottom surfaces of the thermally conductive trench fill material portions 76 are more proximal to the first horizontal plane HP1 than any of the electrically conductive layers 46 in the alternating stacks (32, 46) are to the first horizontal plane HP1. In one embodiment, the bottom surfaces of the lateral isolation trench fill structures (74, 76) are located below the first horizontal plane HP1.

In one embodiment, bottom surfaces of the thermally conductive trench fill material portions 76 may be vertically spaced from the first horizontal plane by a vertical spacing VS. In one embodiment, the bottom portions of the thermally insulating spacers 74 may underlie a respective one of the thermally conductive trench fill material portions 76, and may have a respective vertical extent (i.e., a vertical distance VD) that is greater than the vertical spacing VS.

In one embodiment, a source-side electrode layer 48 is interposed between each of the alternating stacks (32, 46) and the first horizontal plane HP1. In one embodiment, the source-side electrode layer 48 laterally surrounds a subset of the memory opening fill structures 58. In one embodiment, each source-side electrode layer 48 may be in contact with a pair of the thermally insulating spacers 74.

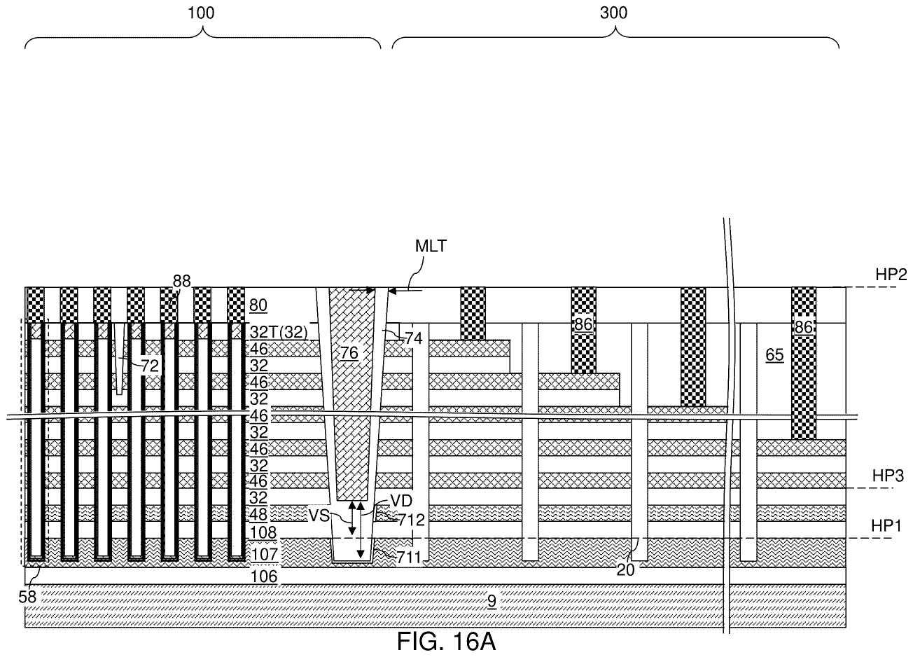

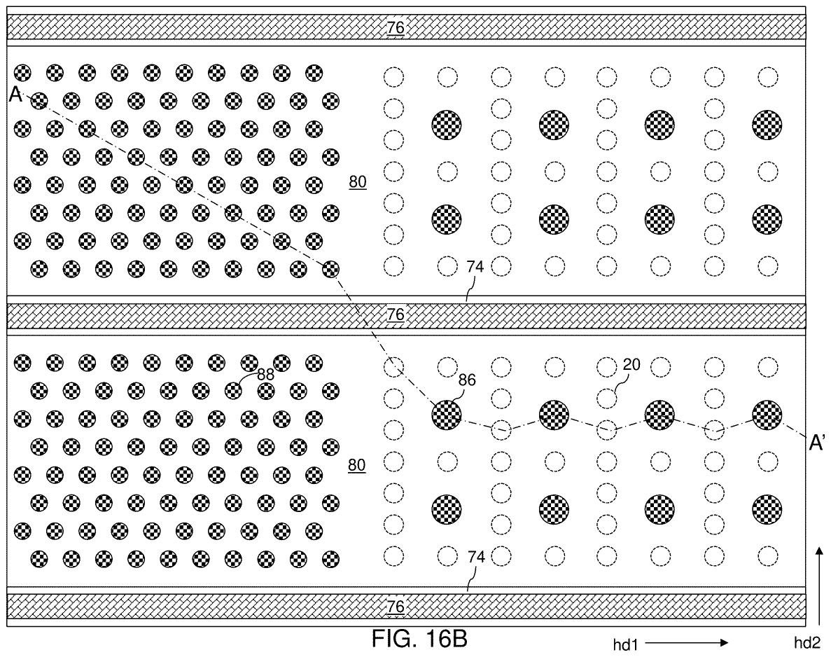

Referring to FIGS. 16A and 16B, contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

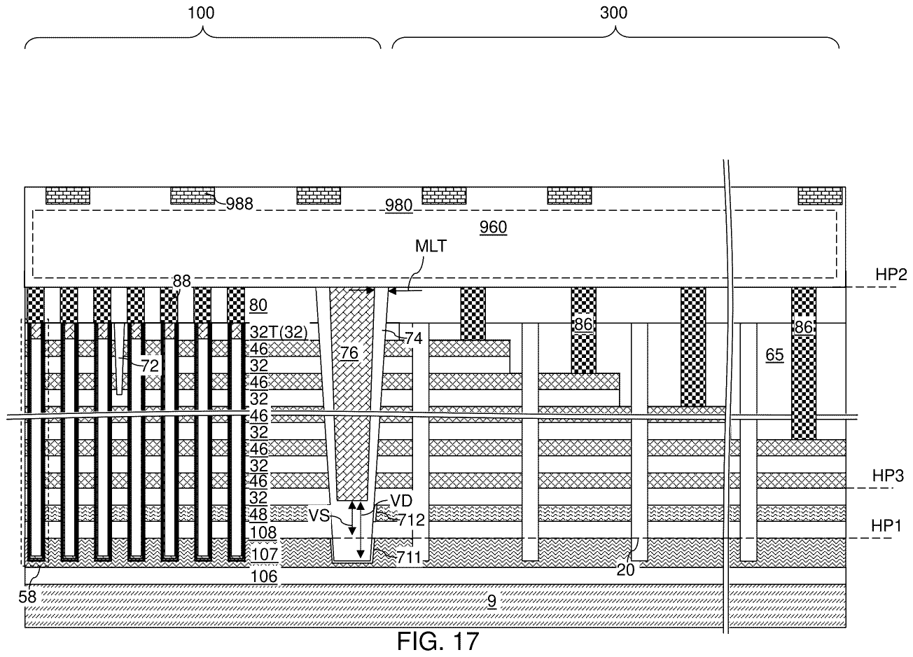

Referring to FIG. 17, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

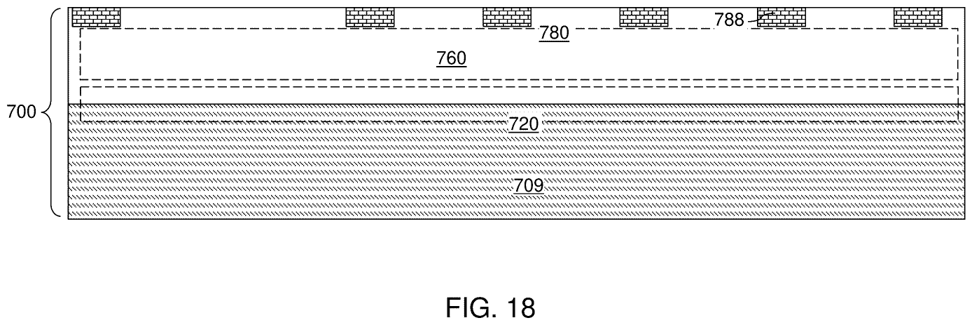

Referring to FIG. 18, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

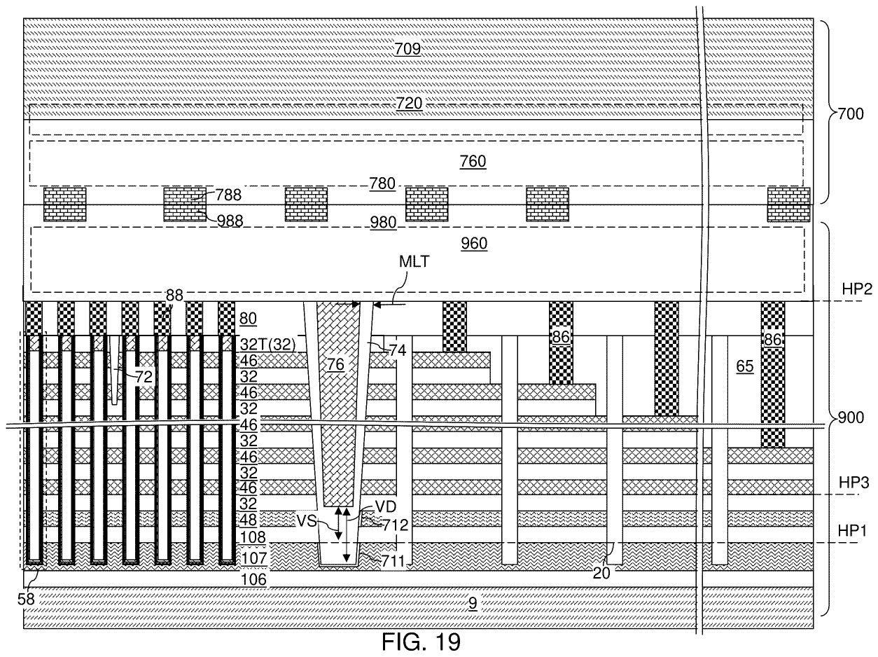

Referring to FIG. 19, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

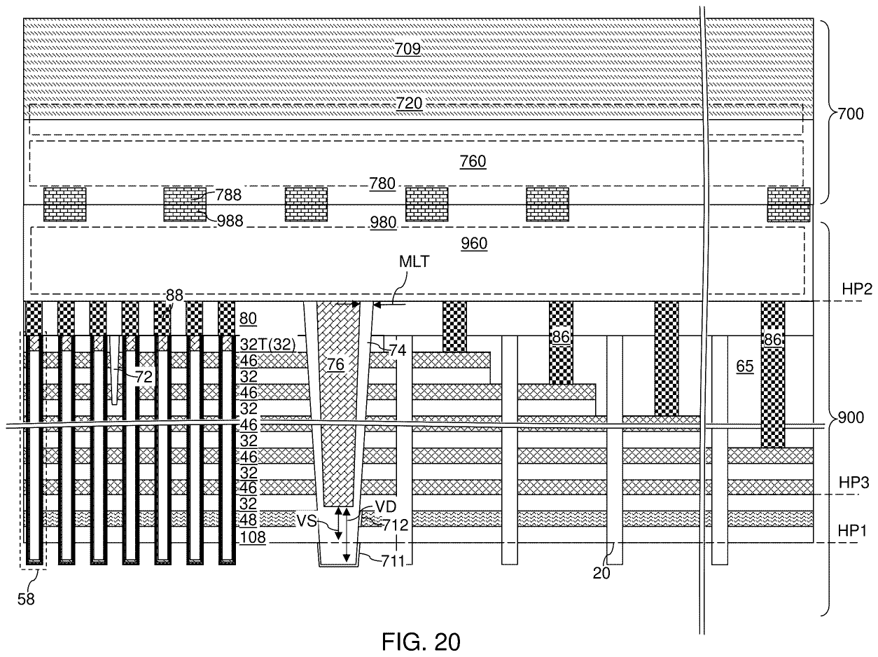

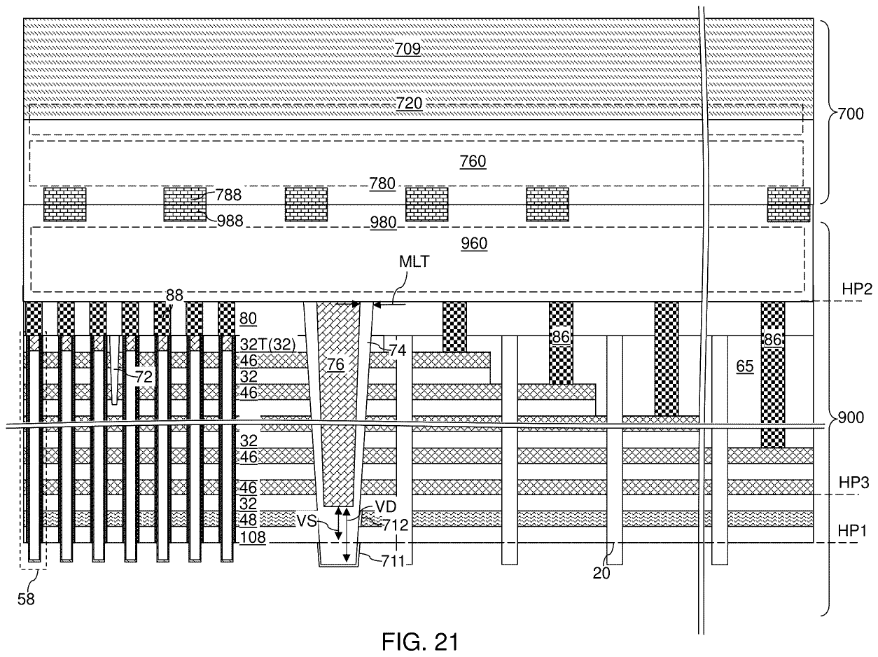

Referring to FIG. 20, the carrier substrate 9, the optional sacrificial stopper layer 106, and the optional sacrificial etch-stop layer 107 may be sequentially removed. The carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the optional sacrificial stopper layer 106 may be employed as a polish stop or etch stop, respectively. Subsequently, the optional sacrificial stopper layer 106 may be removed selectively to the material of the sacrificial etch-stop layer 107, such as by selective etching. Then, the sacrificial etch-stop layer 107 may be removed selectively to the materials of the source isolation dielectric layer 108, the support pillar structures 20, the memory films 50 of the memory opening fill structures 58, and the first dielectric isolation liners 711. For example, if the sacrificial etch-stop layer 107 comprises a semiconductor material, a wet etch process using hot trimethyl-2 hydroxyethyl ammonium hydroxide (“hot TMY”) or tetramethyl ammonium hydroxide (TMAH) may be performed to remove the sacrificial etch-stop layer 107 selectively to the materials of the source isolation dielectric layer 108, the support pillar structures 20, the memory films 50 of the memory opening fill structures 58, and the first dielectric isolation liners 711. The bottom surface of the source isolation dielectric layer 108 may be physically exposed.

Referring to FIG. 21, an end portion of each memory film 50 may be removed by performing a sequence of wet etch processes. In one embodiment, the sequence of wet etch processes may comprise a first wet etch process that etches the material of the blocking dielectric layer 52 selective to the material of the memory material layer 54, a second wet etch process that etches the material of the memory material layer 54 selective to the material of the dielectric liner 56, and a third wet etch process that etches the material of the dielectric liner 56 selective to the material of the vertical semiconductor channel 60. Upon removal of the end portion of the memory film 50, an end portion of each vertical semiconductor channel 60 may be physically exposed.

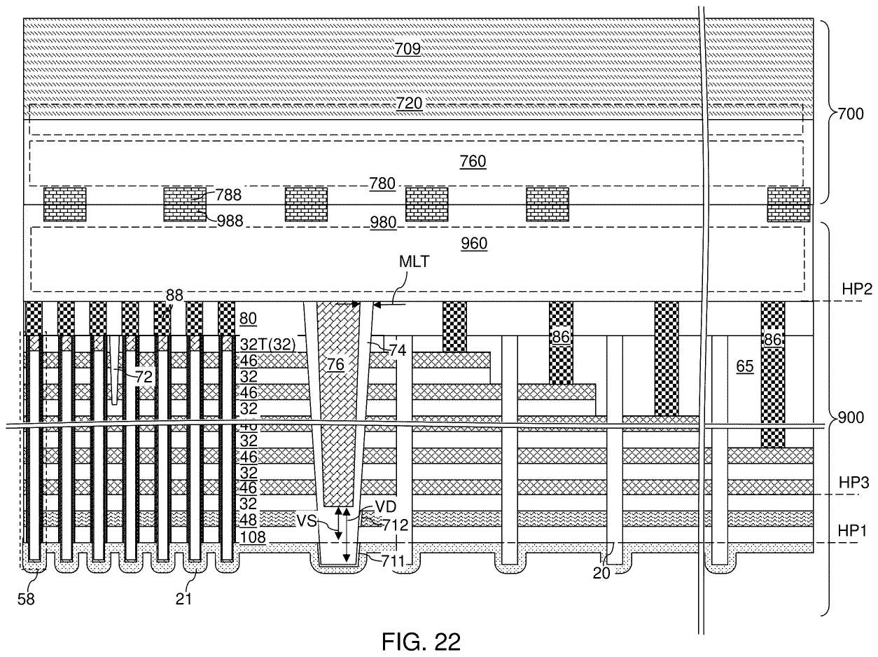

Referring to FIG. 22, an amorphous semiconductor material can be deposited on the physically exposed surfaces of the bottom ends of the vertical semiconductor channels 60 and on the physically exposed bottom surface of the source isolation dielectric layer 108 to form an amorphous semiconductor source layer 21. For example, the amorphous semiconductor source layer 21 may be deposited by relatively low temperature process, such as a plasma-enhanced chemical vapor deposition process, which does not cause significant damage or reflow of the bonding pads (788, 988). The amorphous semiconductor source layer 21 may be in-situ doped with electrical dopants of the second conductivity type (e.g., n-type) which is the opposite of the first conductivity type (which is the conductivity type of the semiconductor material in the vertical semiconductor channels 60). Alternatively, an ion implantation process may be performed to implant dopants of the second conductivity type into the amorphous semiconductor source layer 21. The atomic concentration of the electrical dopants of the second conductivity type in the amorphous semiconductor source layer 21 may be in a range from 5.0×10¹⁸/cm³ to 2.0×10²¹/cm³, although lesser and greater atomic concentrations may also be employed. The vertical thickness of horizontally-extending portions of the amorphous semiconductor source layer 21 may be in a range from 30 nm to 600 nm, although lesser and greater thicknesses may also be employed.

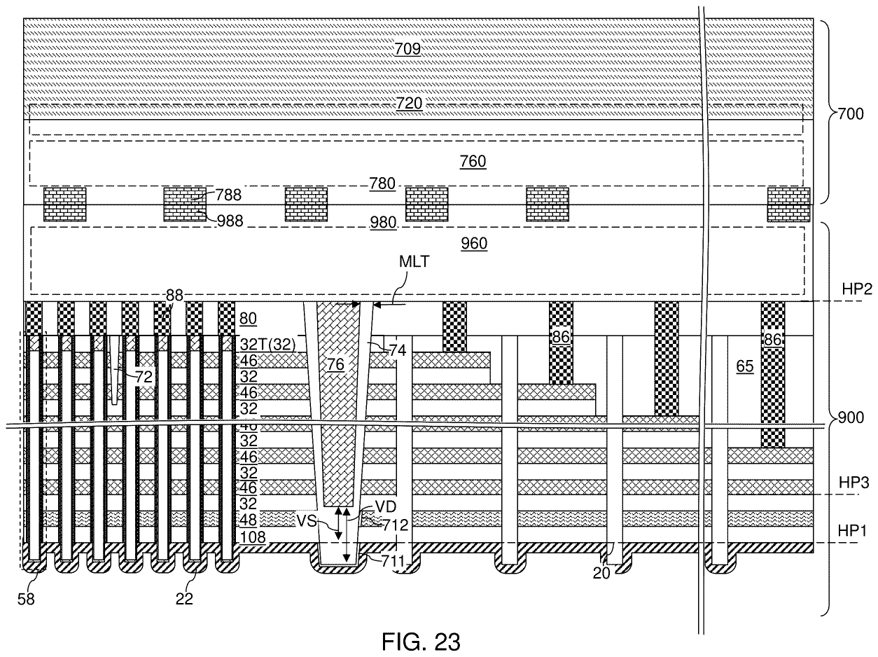

Referring to FIG. 23, a laser anneal process can be performed to crystallize the amorphous semiconductor material in the amorphous semiconductor source layer 21 into a polycrystalline semiconductor material. A laser beam can impinge on the amorphous semiconductor source layer 21 from underneath the memory die 900 on the physically exposed bottom surface of the amorphous semiconductor source layer 21 during the laser anneal process. It is understood that the first exemplary structure may be oriented in any orientation during the laser anneal process provided that the laser beam can impinge on the amorphous semiconductor source layer 21 without passing through the logic die 700 or the memory-side metal interconnect structures 980. The amorphous semiconductor source layer 21 is converted into a polycrystalline semiconductor source layer 22, which functions as a source or as a portion of a source for the vertical NAND strings including the memory opening fill structures 58.

The polycrystalline semiconductor source layer 22 underlies the alternating stacks (32, 46), and contacts bottom surfaces of the vertical semiconductor channels 60. The topmost surface of the polycrystalline semiconductor source layer 22 can be formed within the first horizontal plane HP1. The alternating stacks (32, 46) are laterally spaced apart from each other by the lateral isolation trench fill structures (74, 76). Each of the lateral isolation trench fill structures (74, 76) comprises a thermally insulating spacer 74 and a thermally conductive trench fill material portion 76 embedded within the thermally insulating spacer 74 and having a bottommost surface that is vertically spaced from the first horizontal plane HP1 by a vertical spacing VS that is greater than a maximum lateral thickness MLT of the thermally insulating spacer 74 in the second horizontal plane HP2.

The vertical spacing VS between the proximal surface (i.e., the bottom surface) of each thermally conductive trench fill material portion 76 and the first horizontal plane HP1 is greater than the maximum lateral thickness MLT of the thermally insulating spacers 74 in the second horizontal plane HP2. By increasing the vertical distance between each thermally conductive trench fill material portion 76 and the polycrystalline semiconductor source layer 22, the thermally conductive material 76 within the lateral isolation trenches 79 is positioned further away from the heat generated during the laser anneal process. This configuration reduces the heat diffusion and dissipation through the thermally conductive trench fill material portion 76, which can lead to non-uniform crystallization of the polycrystalline semiconductor source layer 22 and degrade the performance of the memory device.

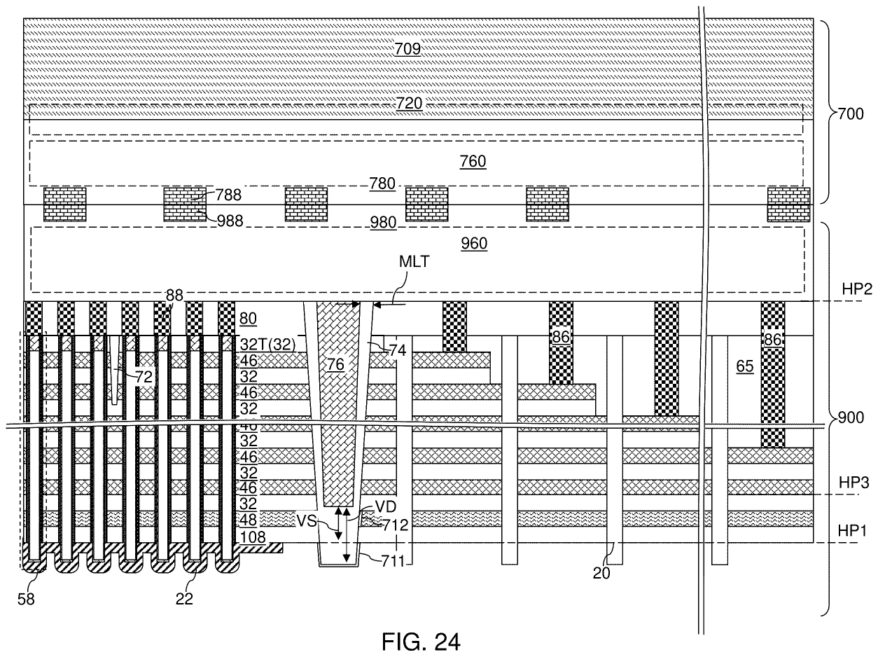

Referring to FIG. 24, the polycrystalline semiconductor source layer 22 may be patterned to remove portions that are located outside the memory array region. Optionally, the polycrystalline semiconductor source layer 22 may be patterned into multiple discrete portions. Optionally, additional electrically conductive layer or layers (e.g., TiN, Al, W, etc.) may be deposited on the polycrystalline semiconductor source layer 22 to increase the conductivity of the source structure.

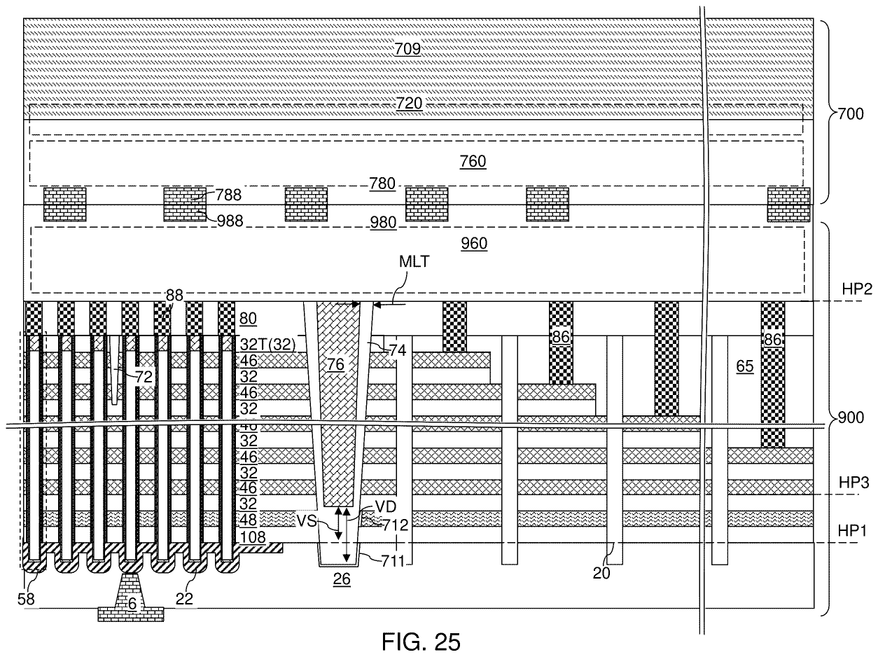

Referring to FIG. 25, a backside dielectric layer 26 and source contact structures 6 may be formed. Additional backside dielectric material layers (not shown) and metal bonding structures (not shown) may be formed as needed.

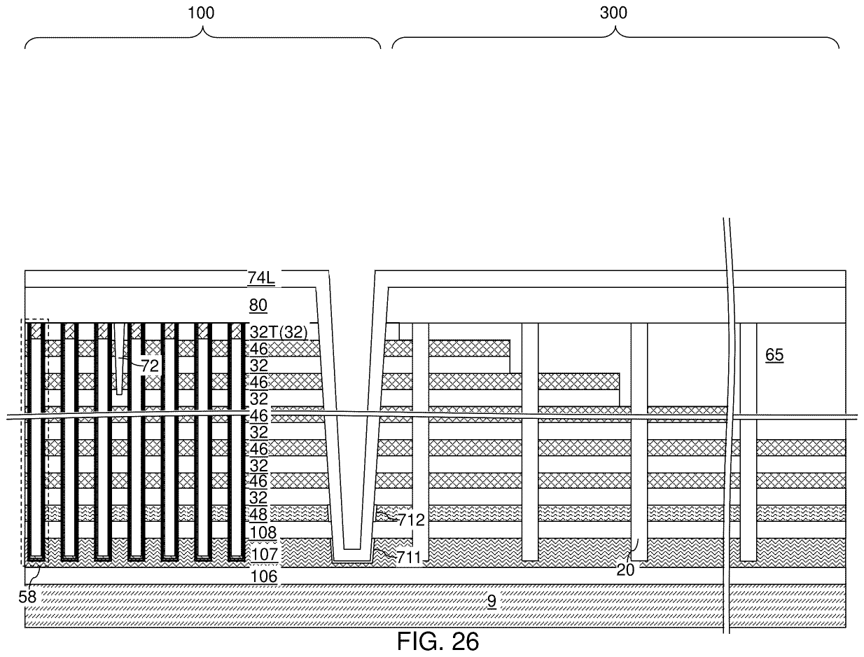

Referring to FIG. 26, a second exemplary structure according to an embodiment of the present disclosure may be derived from the first exemplary structure illustrated in FIG. 12 by depositing a thermally insulating material layer 74L employing a conformal or non-conformal deposition process. In other words, the thermally insulating material layer 74L in the second exemplary structure may be deposited employing a conformal deposition process or a non-conformal deposition process. The thickness of the vertically-extending portions of the thermally insulating material layer 74L may be in a range from 20 nm to 120 nm, although lesser and greater thicknesses may also be employed.

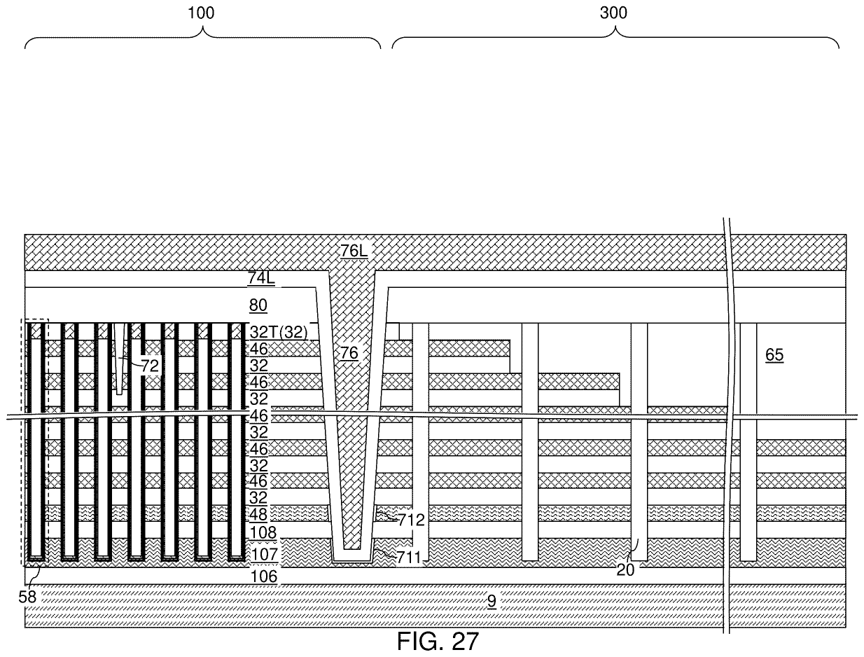

Referring to FIG. 27, the processing steps described with reference to FIG. 14 may be performed to form the thermally conductive fill material layer 76L.

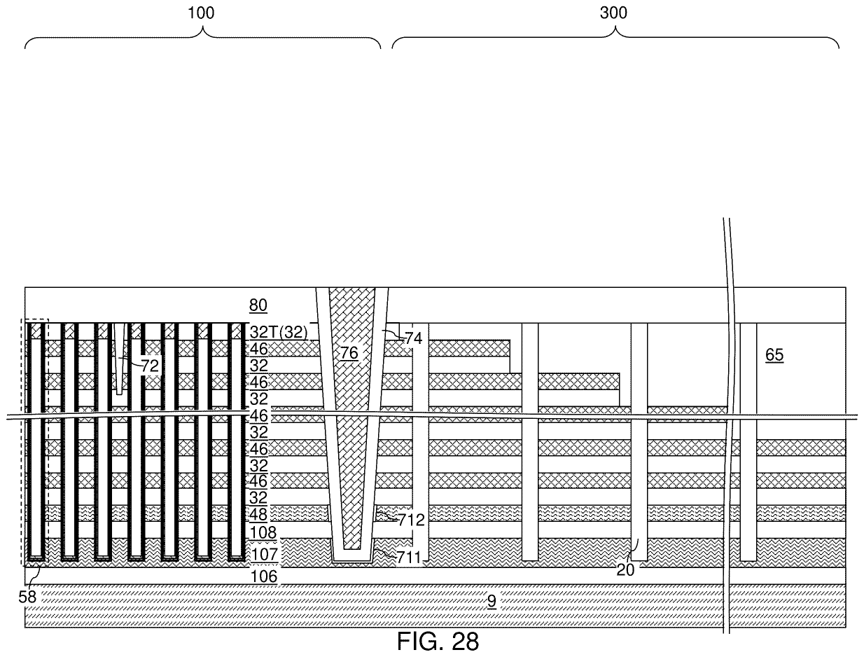

Referring to FIG. 28, a planarization process can be performed to remove portions of the thermally conductive fill material layer 76L and the thermally insulating material layer 74L that overlie a horizontal plane including top surfaces of the contact-level dielectric layers 80, as described with reference to FIG. 15. The planarization process may comprise at least one recess etch process and/or at least one chemical mechanical polishing process. In one embodiment, at least a terminal step of the planarization process may comprise a chemical mechanical polishing process. Each remaining portion of the thermally conductive fill material layer 76L comprises a thermally conductive trench fill material portion 76. Each remaining portion of the thermally insulating material layer 74L comprises a thermally insulating spacer 74. Each contiguous combination of a thermally insulating spacer 74 and a thermally conductive trench fill material portion 76 constitutes a lateral isolation trench fill structure (74, 76).

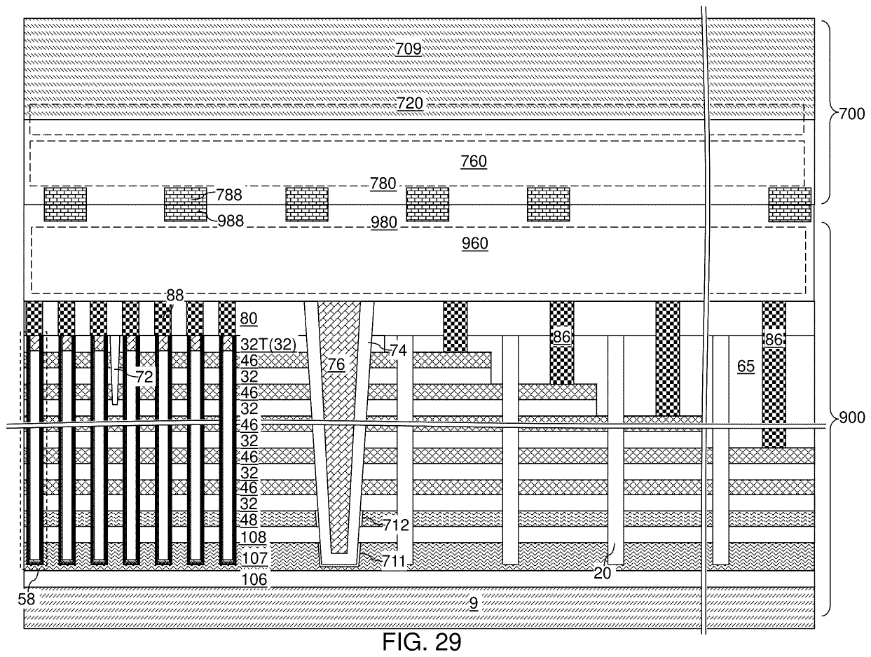

Referring to FIG. 29, the processing steps described with reference to FIGS. 16A, 16B, 17, 18, and 19 can be performed to form a memory die 900, and to attach the memory die 900 to a logic die 700.

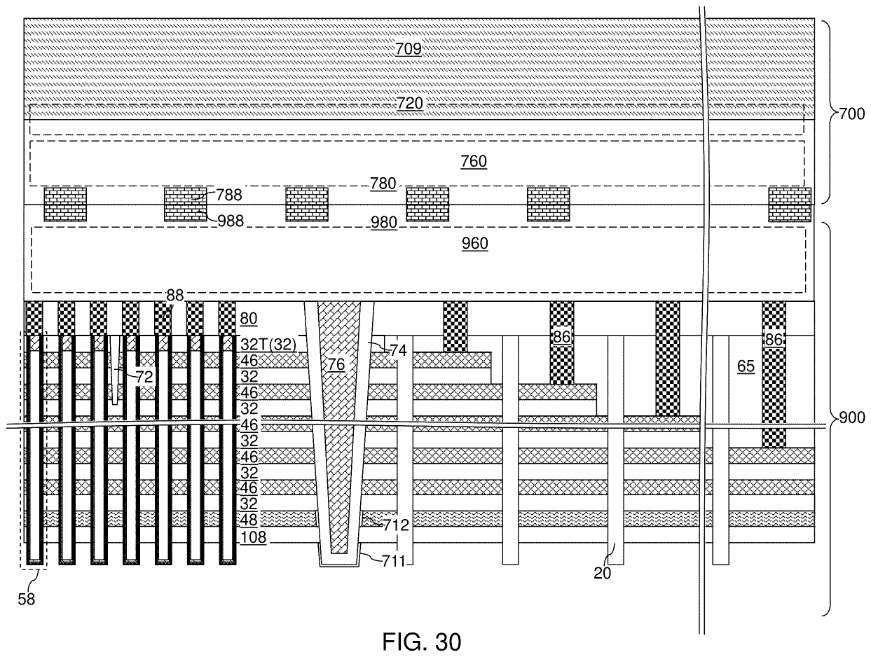

Referring to FIG. 30, the processing steps described with reference to FIG. 20 may be performed to remove the carrier substrate 9, the optional sacrificial stopper layer 106, and the optional sacrificial etch-stop layer 107. The removal of the sacrificial etch-stop layer 107 may be performed selectively to the materials of the memory films 50 and selectively to the lateral isolation trench fill structures (74, 76).

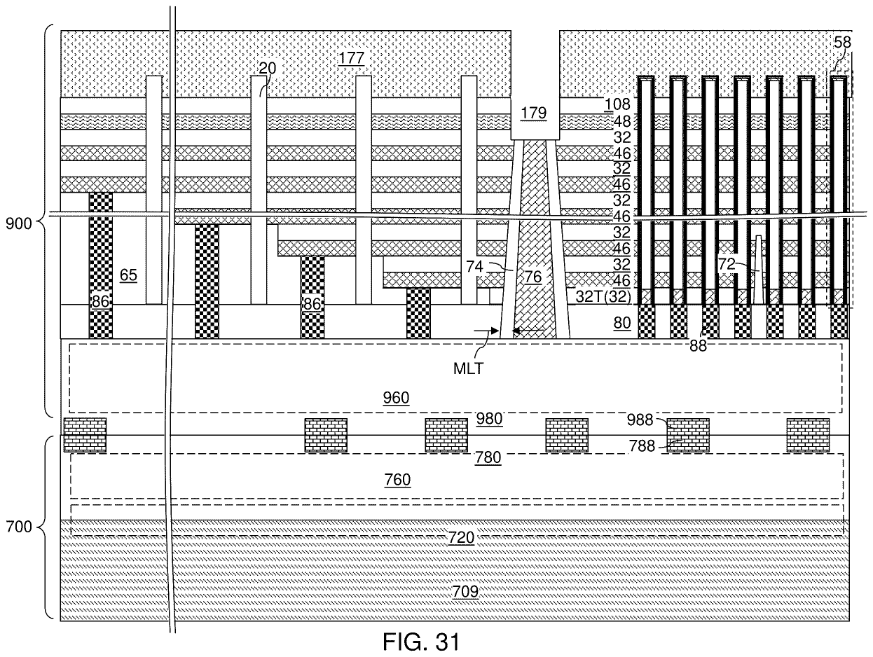

Referring to FIG. 31, the second exemplary structure can be oriented such that the memory die 900 overlies the logic die 700. A patterned photoresist layer 177 can be formed over the source isolation dielectric layer 108. For example, a blanket photoresist material layer can be applied over the source isolation dielectric layer 108, and can be lithographically patterned to form the patterned photoresist layer 177. According to an aspect of the present disclosure, areas of openings in the patterned photoresist layer 177 can include areas overlying the thermally conductive trench fill material portions 76. In one embodiment, areas of the openings in the patterned photoresist layer 177 may include the entirety of the areas overlying the proximal horizontal surfaces of the thermally conductive trench fill material portions 76 (which are bottom horizontal surfaces of the thermally conductive trench fill material portions 76 if the second exemplary structure is viewed in an orientation in which the logic die 700 overlies the memory die 900).

An anisotropic etch process can be performed employing the patterned photoresist layer 177 as an etch mask. The pattern of the openings in the patterned photoresist layer 177 can be transferred through the thermally insulating spacer 74, the source isolation dielectric layer 108 and the source-side electrode layers 48, and optionally into and/or through a subset of layers within each alternating stack (32, 46). Backside shallow trenches 179 are formed in the volumes from which the materials of the thermally insulating spacer 74, the source isolation dielectric layer 108, the source-side electrode layers 48, and the alternating stacks (32, 46) are removed. Generally, the anisotropic etch process removes proximal portions of the lateral isolation trench fill structures (74, 76) (e.g., at least bottom portions of the thermally insulating spacers 74 when the second exemplary structure is viewed in an orientation in which the logic die 700 overlies the memory die 900). According to an aspect of the present disclosure, the recess depth of the backside shallow trenches 179 is greater than a maximum lateral thickness MLT of each of the thermally insulating spacers 74 in the second horizontal plane HP2. In one embodiment, each vertically-extending portion of the thermally insulating spacers 74 may have a variable lateral width that increases strictly with a vertical distance from the source isolation dielectric layer 108. The patterned photoresist layer 177 can be subsequently removed, for example, by ashing.

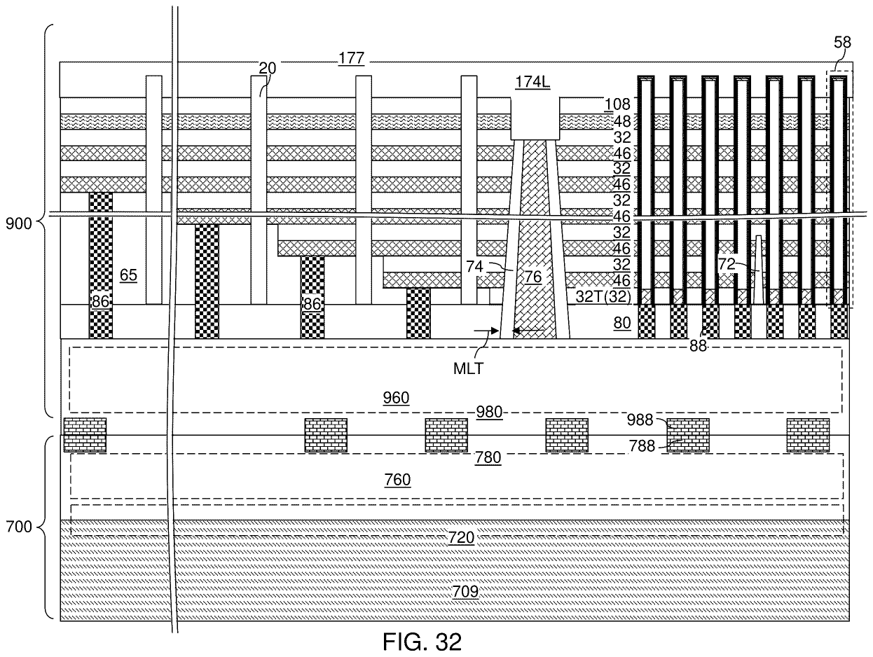

Referring to FIG. 32, a backside dielectric fill material layer 174L can be deposited into the backside shallow trenches 179 and on the physically exposed backside surface of the source isolation dielectric layer 108. The backside dielectric fill material layer 174L comprises a thermally insulating, dielectric (i.e., electrically insulating) fill material, such as undoped silicate glass (i.e., silicon oxide) or a doped silicate glass.

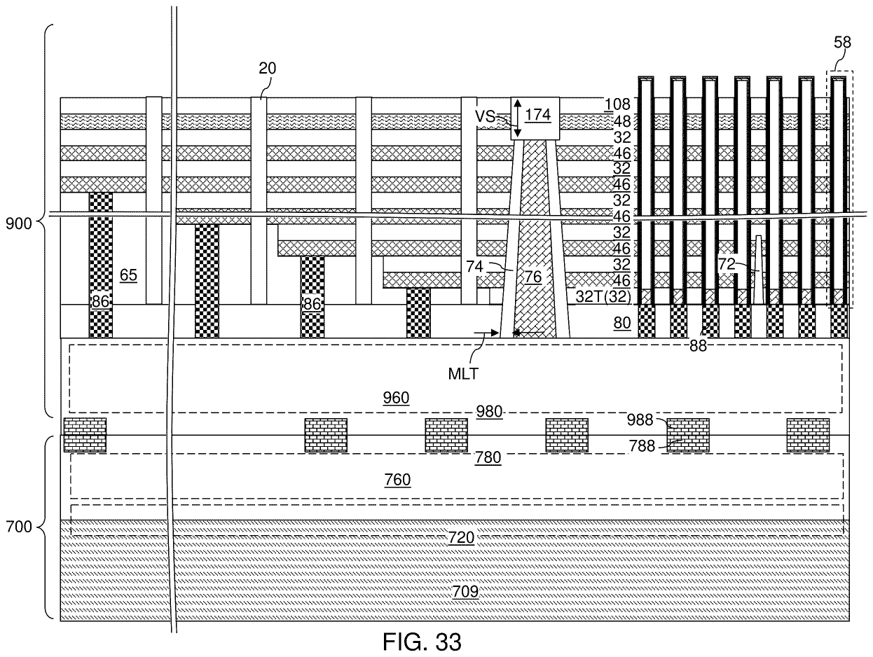

Referring to FIG. 33, a recess etch process can be performed to vertically recess the material of the backside dielectric fill material layer 174L. The recess etch process may comprise an isotropic etch process. such as a wet etch process employing dilute hydrofluoric acid, and/or may comprise a reactive ion etch process that etches the material of the backside dielectric fill material layer 174L. The dielectric materials of the support pillar structures 20 and the end portions of the blocking dielectric layers 52 may be collaterally removed by the recess etch process. The backside surface of the source isolation dielectric layer 108 may be physically exposed. Each remaining portion of the backside dielectric fill material layer 174L filling a respective one of the backside shallow trenches 179 constitutes a backside thermal isolation structure 174. The backside thermal isolation structures 174 comprise a thermally insulating material (e.g., having a thermal conductivity of less an 20 W/m*K), such as silicon oxide, and separate neighboring pairs of stacks of a source isolation dielectric layer 108 and a source-side electrode layer 48.

In one embodiment, each of the lateral isolation trench fill structures (74, 76) comprises a thermally insulating spacer 74 and a thermally conductive trench fill material portion 76 embedded within the thermally insulating spacer 74. A horizontal surface of the thermally conductive trench fill material portion 76 that is most proximal to a horizontal plane including a physically exposed horizontal planes of the source isolation dielectric layers 108 may be vertically spaced from the horizontal plane by a vertical spacing VS that is greater than a maximum lateral thickness MLT of the thermally insulating spacer 74.

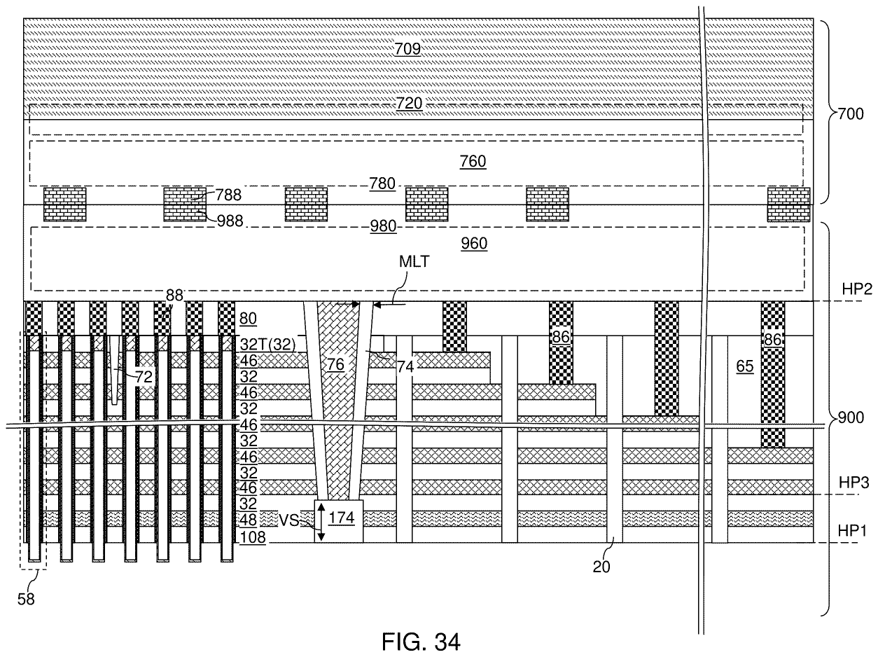

Referring to FIG. 34, the processing steps described with reference to FIG. 21 may be performed to remove physically exposed end portions of the memory films 50.

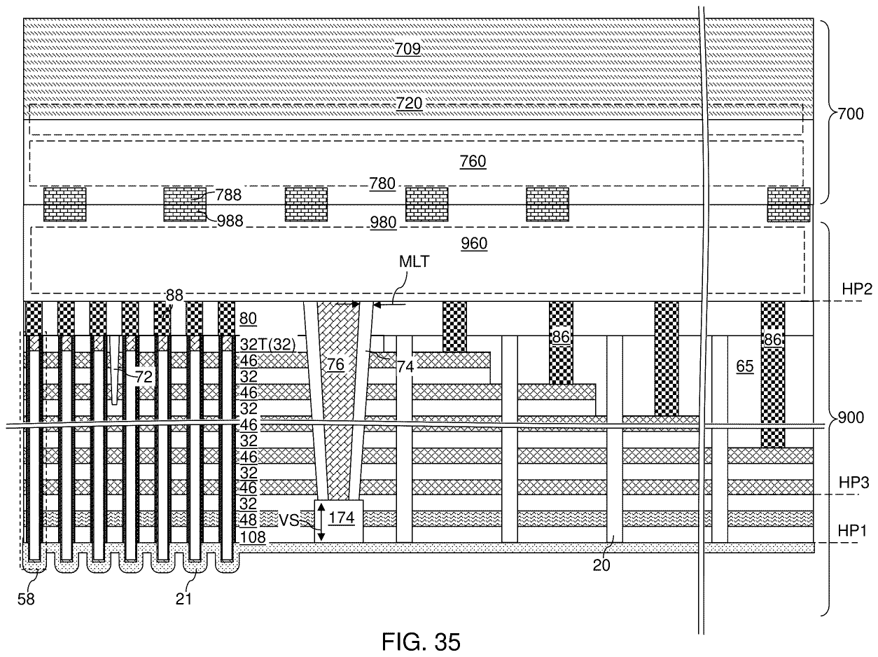

Referring to FIG. 35, the processing steps described with reference to FIG. 22 may be performed to form an amorphous semiconductor source layer 21 on physically exposed bottom end portions of the vertical semiconductor channels 60.

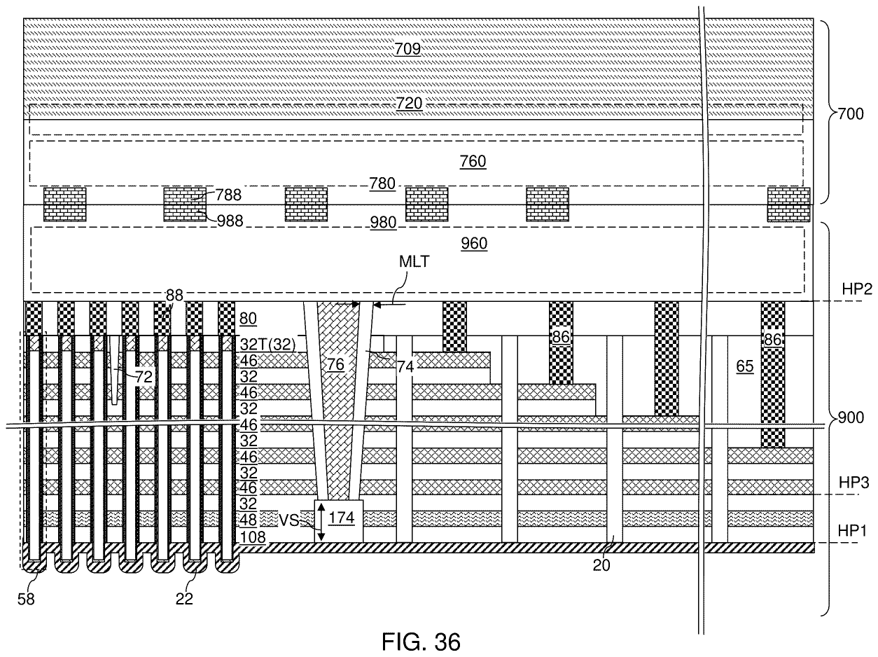

Referring to FIG. 36, the processing steps described with reference to FIG. 23 may be performed to convert the amorphous semiconductor source layer 21 into a polycrystalline semiconductor source layer 22. As described above, a laser beam can be irradiated on the amorphous semiconductor source layer 21 from the bottom side, i.e., through the ambient to which the amorphous semiconductor source layer 21 is exposed.

The polycrystalline semiconductor source layer 22 underlies the alternating stacks (32, 46) and contacts bottom surfaces of the vertical semiconductor channels 60. The polycrystalline semiconductor source layer 22 has a topmost surface within a first horizontal plane HP1. Each of the lateral isolation trench fill structures (74, 76) comprises a thermally insulating spacer 74 and a thermally conductive trench fill material portion 76 embedded within the thermally insulating spacer 74 and having a bottommost surface that is vertically spaced from the first horizontal plane HP1 by a vertical spacing VS that is greater than a maximum lateral thickness MLT of the thermally insulating spacer 74. The backside thermal isolation structure 174 vertically separates the polycrystalline semiconductor source layer 22 from the thermally conductive trench fill material portion 76 by the vertical spacing VS.

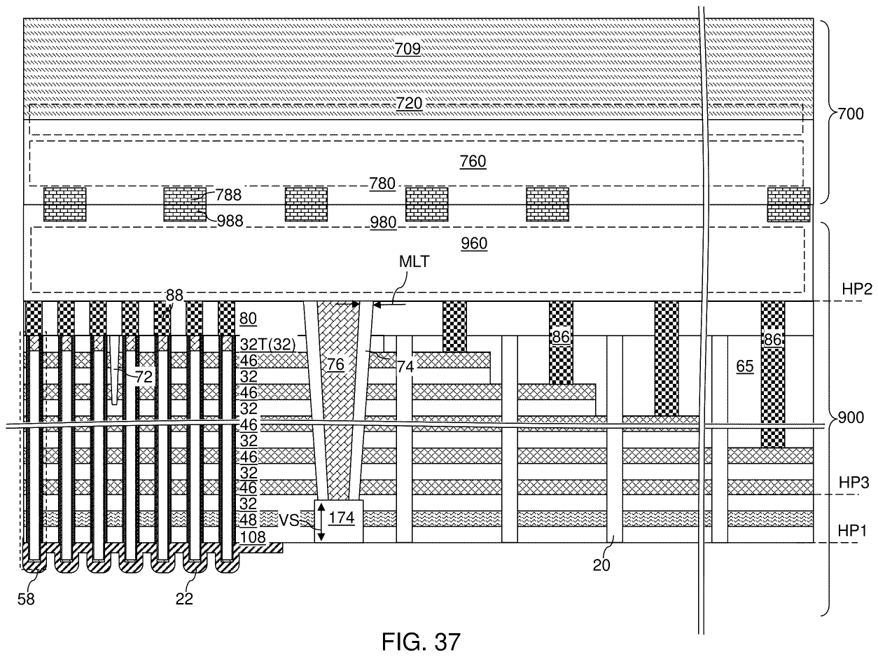

Referring to FIG. 37, the processing steps described with reference to FIG. 24 can be performed to pattern the polycrystalline semiconductor source layer 22.

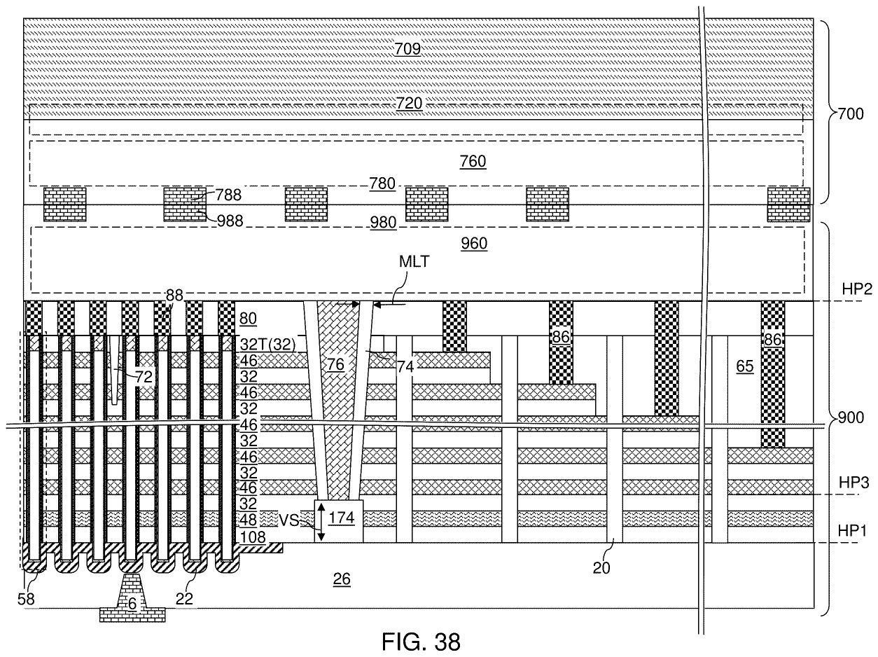

Referring to FIG. 38, the processing steps described with reference to FIG. 25 can be performed to form a backside dielectric layer 26 and source contact structures 6.

Referring to all drawings and according to various embodiments of the present disclosure, a memory device is provided, which comprises: alternating stacks (32, 46) that are laterally spaced apart from each other by lateral isolation trench fill structures (74, 76), wherein each of the alternating stacks (32, 46) comprises a respective vertically alternating sequence of insulating layers 32 and electrically conductive layers 46; memory openings 49 vertically extending through a respective one of the alternating stacks (32, 46); memory opening fill structures 58 located in the memory openings 49, wherein each of the memory opening fill structures 58 comprises a respective vertical semiconductor channel 60 and a respective vertical stack of memory elements (as embodied as portions of a memory film 50); and a polycrystalline semiconductor source layer 22 underlying the alternating stack (32, 46) and contacting bottom surfaces of the vertical semiconductor channels 60. Each of the lateral isolation trench fill structures (74, 76) comprises a thermally conductive trench fill material portion 76 that is vertically spaced from the polycrystalline semiconductor source layer 22 by a thermally insulating material (74, 174).

In one embodiment, the polycrystalline semiconductor source layer 22 has topmost surface within a first horizontal plane HP1; each of the lateral isolation trench fill structures (74, 76) further comprises a thermally insulating spacer 74; and the thermally conductive trench fill material portion is embedded within the thermally insulating spacer 74 and having a bottommost surface that is vertically spaced from the first horizontal plane HP1 by a vertical spacing VS that is greater than a maximum lateral thickness MLT of the thermally insulating spacer 74.

In one embodiment, within each of the lateral isolation trench fill structures (74, 76), the thermally insulating spacer 74 has a variable lateral thickness that increases with a vertical distance from the first horizontal plane HP1. In one embodiment, within each of the lateral isolation trench fill structures (74, 76), all sidewall surfaces of the thermally conductive trench fill material portion 76 are in direct contact with the thermally insulating spacer 74.

In the first embodiment, the thermally insulating spacer 74 comprises a bottom portion located below the thermally conductive trench fill material portion 76, and the thermally conductive trench fill material portion 76 is vertically spaced from the polycrystalline semiconductor source layer 22 by the thermally insulating material of the bottom portion of the thermally insulating spacer 74. In this embodiment, the bottom portion of the thermally insulating spacer 74 contacts both the polycrystalline semiconductor source layer 22 and the bottom portion of the thermally conductive trench fill material portion 76 that is proximal to the first horizontal plane HP1.

In the second embodiment, the memory device also comprises backside thermal isolation structures 174 located between neighboring pairs of the alternating stacks (32, 46) and interposed between a respective one of the lateral isolation trench fill structures (74, 76) and the first horizontal plane HP1. In this embodiment, the thermally conductive trench fill material portion 76 is vertically spaced from the polycrystalline semiconductor source layer 22 by the thermally insulating material of a respective one of the backside thermal isolation structures 174; and each of the backside thermal isolation structures 174 contacts the polycrystalline semiconductor source layer 22, a respective one of the thermally insulating spacers 74 and a respective one of the thermally conductive trench fill material portions 76.

In one embodiment, the memory device also comprises contact-level dielectric layers 80 overlying a respective one of the alternating stacks (32, 46) and laterally spaced apart from each other by the lateral isolation trench fill structures (74, 76). In one embodiment, top surfaces of the lateral isolation trench fill structures (74, 76) are located entirely within a second horizontal plane HP2 including top surfaces of the contact-level dielectric layers 80.

In one embodiment, bottom surfaces of the thermally conductive trench fill material portions 76 are more proximal to the first horizontal plane HP1 than any of the electrically conductive layers 46 in the alternating stacks (32, 46) are to the first horizontal plane HP1. In one embodiment, bottom surfaces of the lateral isolation trench fill structures (74, 76) are located below the first horizontal plane HP1. In one embodiment, bottom portions of the thermally insulating spacers 74 that underlie a respective one of the thermally conductive trench fill material portions 76 have a respective vertical extent that is greater than the vertical spacing VS.

In one embodiment, the thermally insulating material (74, 174) has a thermal conductivity of less than 20 W/m*K, and the thermally conductive trench fill material portions 76 comprise a refractory metal or a refractory metal nitride. In one embodiment, the thermally insulating material (74, 174) comprises silicon oxide; the thermally conductive trench fill material portions 76 comprise tungsten; and the polycrystalline semiconductor source layer 22 comprises doped polysilicon.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
alternating stacks that are laterally spaced apart from each other by lateral isolation trench fill structures, wherein each of the alternating stacks comprises a respective vertically alternating sequence of insulating layers and electrically conductive layers;
memory openings vertically extending through a respective one of the alternating stacks;
memory opening fill structures located in the memory openings, wherein each of the memory opening fill structures comprises a respective vertical semiconductor channel and a respective vertical stack of memory elements; and
a polycrystalline semiconductor source layer underlying the alternating stack and contacting bottom surfaces of the vertical semiconductor channels,
wherein each of the lateral isolation trench fill structures comprises a thermally conductive trench fill material portion that is vertically spaced from the polycrystalline semiconductor source layer by a thermally insulating material.

2. The memory device of claim 1, wherein:
the polycrystalline semiconductor source layer has topmost surface within a first horizontal plane;
each of the lateral isolation trench fill structures further comprises a thermally insulating spacer; and
the thermally conductive trench fill material portion is embedded within the thermally insulating spacer and having a bottommost surface that is vertically spaced from the first horizontal plane by a vertical spacing that is greater than a maximum lateral thickness of the thermally insulating spacer.

3. The memory device of claim 2, wherein within each of the lateral isolation trench fill structures, the thermally insulating spacer has a variable lateral thickness that increases with a vertical distance from the first horizontal plane and all sidewall surfaces of the thermally conductive trench fill material portion are in direct contact with the thermally insulating spacer.

4. The memory device of claim 2, wherein:
the thermally insulating spacer comprises a bottom portion located below the thermally conductive trench fill material portion; and
the thermally conductive trench fill material portion is vertically spaced from the polycrystalline semiconductor source layer by the thermally insulating material of the bottom portion of the thermally insulating spacer.

5. The memory device of claim 4, wherein the bottom portion of the thermally insulating spacer contacts both the polycrystalline semiconductor source layer and the bottom portion of the thermally conductive trench fill material portion that is proximal to the first horizontal plane.

6. The memory device of claim 2, further comprising backside thermal isolation structures located between neighboring pairs of the alternating stacks and interposed between a respective one of the lateral isolation trench fill structures and the first horizontal plane.

7. The memory device of claim 6, wherein:
the thermally conductive trench fill material portion is vertically spaced from the polycrystalline semiconductor source layer by the thermally insulating material of a respective one of the backside thermal isolation structures; and
each of the backside thermal isolation structures contacts the polycrystalline semiconductor source layer, a respective one of the thermally insulating spacers, and a respective one of the thermally conductive trench fill material portions.

8. The memory device of claim 2, further comprising contact-level dielectric layers overlying a respective one of the alternating stacks and laterally spaced apart from each other by the lateral isolation trench fill structures.

9. The memory device of claim 8, wherein top surfaces of the lateral isolation trench fill structures are located entirely within a second horizontal plane including top surfaces of the contact-level dielectric layers.

10. The memory device of claim 2, wherein bottom surfaces of the thermally conductive trench fill material portions are more proximal to the first horizontal plane than any of the electrically conductive layers in the alternating stacks are to the first horizontal plane.

11. The memory device of claim 2, wherein bottom surfaces of the lateral isolation trench fill structures are located below the first horizontal plane.

12. The memory device of claim 2, wherein bottom portions of the thermally insulating spacers that underlie a respective one of the thermally conductive trench fill material portions have a respective vertical extent that is greater than the vertical spacing.

13. The memory device of claim 1, wherein the thermally insulating material has a thermal conductivity of less than 20 W/m*K, and the thermally conductive trench fill material portions comprise a refractory metal or a refractory metal nitride.

14. The memory device of claim 13, wherein:
the thermally insulating material comprises silicon oxide;
the thermally conductive trench fill material portions comprise tungsten; and
the polycrystalline semiconductor source layer comprises doped polysilicon.

15. A method of forming a memory device, comprising:
forming alternating stacks laterally spaced from each other by lateral isolation trenches over a carrier substrate, wherein each of the alternating stacks comprises a respective vertically alternating sequence of insulating layers and electrically conductive layers and embeds a respective set of memory opening fill structures, and wherein each of the memory opening fill structures comprises a respective vertical semiconductor channel and a respective stack of memory elements located at levels of the electrically conductive layers;
forming lateral isolation trench fill structures in the lateral isolation trenches by anisotropically depositing a thermally insulating material in peripheral regions of the lateral isolation trenches and by subsequently depositing a thermally conductive trench fill material in center regions of the lateral isolation trenches, wherein each of the lateral isolation trench fill structures comprises a thermally insulating spacer and a thermally conductive trench fill material portion embedded within the thermally insulating spacer;
removing the carrier substrate and exposing bottom end portions of the vertical semiconductor channels;
depositing an amorphous semiconductor source layer on the exposed bottom end portions of the vertical semiconductor channels; and
crystallizing the amorphous semiconductor source layer into a polycrystalline semiconductor source layer by laser annealing.

16. The method of claim 15, wherein the thermally conductive trench fill material portion has a bottommost surface that is vertically spaced from a bottom surface of the thermally insulating spacer by a vertical distance that is greater than a maximum lateral thickness of the thermally insulating spacer at a top surface of the lateral isolation trench fill structures.

17. The method of claim 15, wherein:
the method further comprises forming a sacrificial etch-stop layer over the carrier substrate;
the alternating stacks are formed over the sacrificial etch-stop layer;
the lateral isolation trenches extend into an upper portion of the sacrificial etch-stop layer; and
the method further comprises removing the sacrificial etch-stop layer after removing the carrier substrate selectively to the lateral isolation trench fill structures.

18. A method of forming a memory device, comprising:
forming alternating stacks laterally spaced from each other by lateral isolation trenches over a carrier substrate, wherein each of the alternating stacks comprises a respective vertically alternating sequence of insulating layers and electrically conductive layers and embeds a respective set of memory opening fill structures, and wherein each of the memory opening fill structures comprises a respective vertical semiconductor channel and a respective stack of memory elements located at levels of the electrically conductive layers;
forming lateral isolation trench fill structures in the lateral isolation trenches by sequentially depositing a thermally and electrically insulating material and a thermally conductive trench fill material, wherein each of the lateral isolation trench fill structures comprises a thermally insulating spacer and a thermally conductive trench fill material portion embedded within the thermally insulating spacer;
removing the carrier substrate;
forming backside shallow trenches by removing bottom portions of the thermally insulating spacers;
forming backside thermal isolation structures in the backside shallow trenches;
exposing bottom end portions of the vertical semiconductor channels;
depositing an amorphous semiconductor source layer on the exposed bottom end portions of the vertical semiconductor channels; and
crystallizing the amorphous semiconductor source layer into a polycrystalline semiconductor source layer by laser annealing.

19. The method of claim 18, wherein:
the backside thermal isolation structures comprise silicon oxide;
the thermally conductive trench fill material portions comprise tungsten; and
the polycrystalline semiconductor source layer comprises doped polysilicon.

20. The method of claim 18, further comprising:
forming a sacrificial etch-stop layer and a source isolation dielectric layer over the carrier substrate, wherein the alternating stacks are formed over the source isolation dielectric layer;
removing the sacrificial etch-stop layer after removing the carrier substrate selectively to the lateral isolation trench fill structures;
forming a patterned photoresist layer on the source isolation dielectric layer such that areas of openings in the patterned photoresist layer overlie areas of the thermally conductive trench fill material portions; and
performing an anisotropic etch process employing the patterned photoresist layer as an etch mask to form the backside shallow trenches.
